(19) United States
(12) Patent Application Publication
(10) Pub. No.: US 2017/0165879 A1
(43) Pub. Date: Jun. 15, 2017

(54) RESIN PRECURSOR, RESIN COMPOSITION CONTAINING SAME, POLYIMIDE RESIN MEMBRANE, RESIN FILM, AND METHOD FOR PRODUCING SAME

(71) Applicant: ASAHI KASEI KABUSHIKI KAISHA, Tokyo (JP)

(72) Inventors: Yoshiki MIYAMOTO, Tokyo (JP); Toshiaki OKUDA, Tokyo (JP); Masaki MAITANI, Tokyo (JP); Yasuhito IIZUKA, Tokyo (JP); Takayuki KANADA, Tokyo (JP)

(73) Assignee: ASAHI KASEI KABUSHIKI KAISHA, Tokyo (JP)

(21) Appl. No.: 15/319,508

(22) PCT Filed: Jul. 13, 2015
(86) PCT No.: PCT/JP2015/070073

§ 371 Date: Dec. 16, 2016

(30) Foreign Application Priority Data
Jul. 17, 2014 (JP) 2014-147186

(51) Int. Cl. B29C 41/00; B29C 41/42; B29C 35/08; B29C 33/60; G02F 1/1337; C08L 79/08; C08J 5/18; H01L 27/12; G02F 1/1333; B29C 41/02; C23C 16/34

(52) U.S. Cl. CPC B29C 41/003; B29C 41/02; B29C 41/42; B29C 35/0805; B29C 33/60; C23C 16/345; C08L 79/08; C08J 5/18; H01L 27/1218; H01L 27/1259; G02F 1/133305; G02F 1/133723; B29C 2035/0838; B29K 2079/08

(57) ABSTRACT

Provided is a resin composition including a polyimide precursor that has exceptional adhesiveness to glass substrates and that does not generate particles during laser detachment. A resin composition containing (a) a polyimide precursor, (b) an organic solvent, and (d) an alkoxysilane compound, wherein the resin composition shows polyimide obtained by imidation of the (a) polyimide precursor after application of the resin composition to the surface of a support, the residual stress with the support is from −5 MPa to 10 MPa, and the 308 nm absorbance of the (d) alkoxysilane compound when made into a 0.001 mass % NMP solution is from 0.1 to 0.5 at a solution thickness of 1 cm.

### TECHNICAL FIELD

The present invention relates to a resin precursor and resin composition containing the same that are used in a substrate for a flexible device, a polyimide resin film, a resin film and a production method thereof, a laminate and a production method thereof, and a display substrate and a production method thereof.

### BACKGROUND ART

Films made of polyimide (PI) resin are typically used as resin films in applications requiring high heat resistance. Typical polyimide resins are highly heat resistant resins that are produced by solution-polymerizing an aromatic dianhydride and aromatic diamine to produce a polyimide precursor followed by carrying out ring closure and dehydration at a high temperature followed by thermal imidization or chemical imidization using a catalyst.

Polyimide resins are insoluble and infusible ultra-heat-resistant resins that have superior properties such as thermal oxidation resistance, heat-resistant properties, radiation resistance, low-temperature resistance and chemical resistance. Consequently, polyimide resins are used in a wide range of fields including insulating coating agents, insulating films, semiconductors and electronic materials such as the electrode protective coatings of TFT-LCD, and more recently, have been considered for use in colorless, transparent flexible substrates by taking advantage of their light weight and flexibility as an alternative to glass substrates conventionally used in the field of display materials in the manner of liquid crystal alignment films.

However, since typical polyimide resins have a brown or yellow color due to their high aromatic ring density, they demonstrate low transmittance in the visible light region, making their use difficult in fields requiring transparency. Therefore, a method has been proposed for inhibiting the formation of charge-transfer complexes allowing the manifestation of transparency by introducing fluorine into the polyimide resin, imparting flexibility to the main chain and introducing a bulky side chain (Non-Patent Document 1).

Here, by changing the monomer ratio of a polyimide resin obtained from a group of acid dianhydrides consisting of pyromellitic dianhydride (PMDA) and 4,4′-(hexafluoroisopropylidene)diphthalic anhydride (6FDA) and a diamine in the form of 2,2′-bis(trifluoromethyl)benzidine (TFMB), refractive index was able to be controlled as desired, thereby enabling the polyimide resin to be used as an optical waveguide material (Patent Document 1).

In addition, polyimide resins obtained from PMDA, 6FDA and TFMB have been described as having superior optical transmittance, yellow index (YI) value and coefficient of thermal expansion (CTE), and being able to be applied as LCD materials (Patent Documents 2 and 3).

Since polyimide resins obtained from PMDA, 6FDA and TFMB also have a small difference in CTE from gas barrier films (inorganic films), display devices have been proposed that are provided with a gas barrier layer on the aforementioned polyimide resin (Patent Document 4).

In addition, a resin composition having a polyimide precursor and an alkoxysilane compound has been proposed for use in flexible device applications (Patent Document 5).

### PRIOR ART DOCUMENTS

### Patent Documents

Patent Document 1: Japanese Unexamined Patent Publication No. H4-008734
Patent Document 2: Japanese Translation of PCT International Application Publication No. 2010-538103
Patent Document 3: Korean Unexamined Patent Publication No. 10-2014-0049382
Patent Document 4: International Publication No. WO 2013/191180
Patent Document 5: International Publication No. WO 2014/073591

### Non-Patent Documents

Non-Patent Document 1: Polymer (U.S.), Vol. 47, p. 2337-2348

### DISCLOSURE OF THE INVENTION

### Problems to be Solved by the Invention

However, the physical properties of known transparent polyimides were not adequate for use as semiconductor insulating films, TFT-LCD insulating films, electrode protective films, touch panel ITO electrode substrates or heat-resistant, colorless and transparent substrates for flexible displays.

In recent years, indium-gallium-zinc-oxide (IGZO) and the like has come to be used as a TFT material in organic EL display processes, resulting in a greater demand for low CTE materials. In the case of the polyimide resin described in Patent Document 2, the CTE value is 27, resulting in the problem of an excessively high CTE.

Although CTE is low in the case of the polyimide resin described in Patent Document 3, when confirmed by the inventor of the present invention, this polyimide resin was determined to have the problem of poor coatability of a resin composition containing this polyimide resin in the case of the solvent used in the examples (Comparative Example 3 to be subsequently described).

In the case of the polyimide resin described in Patent Document 4, CTE was equal to that of an inorganic film. However, when the method described in Patent Document 4 used to detach the polyimide resin from a support was confirmed by the inventor of the present invention, it was determined to have problems consisting of a large YI value of the polyimide film following detachment, low degree of elongation and a large difference in refractive indices between the front and back sides (Comparative Example 2 to be subsequently described).

In addition, in the case of the polyimide resin and alkoxysilane compound described in Patent Document 5, a polyimide resin is disclosed that demonstrates high residual stress. When examined by the inventors of the present invention, although little energy is required when detaching the polyimide film from a glass substrate by laser detachment in the case of a polymer having high residual stress, in the case of a polymer having low residual stress, there was the problem of the generation of particles during laser detachment due to the large amount of energy required.

With the foregoing in view, an object of a first aspect of the present invention is to provide a resin composition that has favorable adhesiveness with a glass substrate and does not generate particles during laser detachment, in the case of a polymer having low residual stress.

With the foregoing in view, another object of the first aspect of the present invention is to provide a resin composition containing a polyimide precursor that has favorable adhesiveness with a glass substrate and does not generate particles during laser detachment.

With the foregoing in view, an object of a second aspect of the present invention is to provide a resin composition containing a polyimide precursor that has superior storage stability and coatability. In addition, an object of the present invention is to provide a polyimide resin film, which has low residual stress, low yellow index (YI) value, little effect of oxygen concentration during curing (heat curing step) on YI value and total light transmittance, and a small difference in refractive indices between the front and back sides, a resin film and a production method thereof, and a laminate and a production method thereof. Moreover, an object of the present invention is to provide a display substrate having a small difference in refractive indices between the front and back sides and a low yellow index value, and a production method thereof.

### Means for Solving the Problems

As a result of conducting extensive studies to solve the aforementioned problems, the inventors of the present invention found that, in a first aspect, a polyimide precursor, which generates residual stress within a specific range with a substrate when in the form of a polyimide, and an alkoxysilane compound having a specific ratio of absorbance at 308 nm, demonstrate superior adhesiveness with a glass substrate (support) and do not generate particles during laser detachment; and

in a second aspect, the inventors of the present invention found that a resin composition containing a polyimide precursor having a specific structure has superior storage stability and superior coatability,

a polyimide film obtained by curing the composition has low residual stress, low yellow index (YI) value, and little effect of oxygen concentration during the curing step on YI value and total light transmittance,

an inorganic film formed on the polyimide film has a low haze value, and

by using laser detachment and/or layer detachment as the method for detaching the polyimide resin film from the support, a small difference in refractive indices between the front and back sides of the resin film and a low YI value are satisfied,

thereby leading to completion of the present invention on the basis of these findings.

Namely, the present invention is as described below.

[1] A resin composition containing a polyimide precursor (a), an organic solvent (b) and an alkoxysilane compound (d); wherein,

after having coated the resin composition onto the surface of a support, residual stress with the support demonstrated by a polyimide obtained by imidizing the polyimide precursor (a) is −5 MPa to 10 MPa, and

absorbance of the alkoxysilane compound (d) at 308 nm when in the form of a 0.001% by weight NMP solution is 0.1 to 0.5 at a solution thickness of 1 cm.

[2] The resin composition described in [1], wherein the alkoxysilane compound (d) is a compound obtained by reacting an acid dianhydride represented by the following general formula (1):

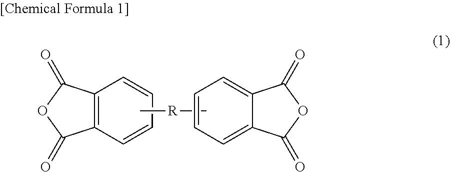

(wherein, R represents a single bond, oxygen atom, sulfur atom or alkylene group having 1 to 5 carbon atoms) with an aminotrialkoxysilane compound.

[3] The resin composition described in [1] or [2], wherein the alkoxysilane compound (d) is at least one type of compound selected from the group consisting of compounds respectively represented by the following general formulas (2) to (4).

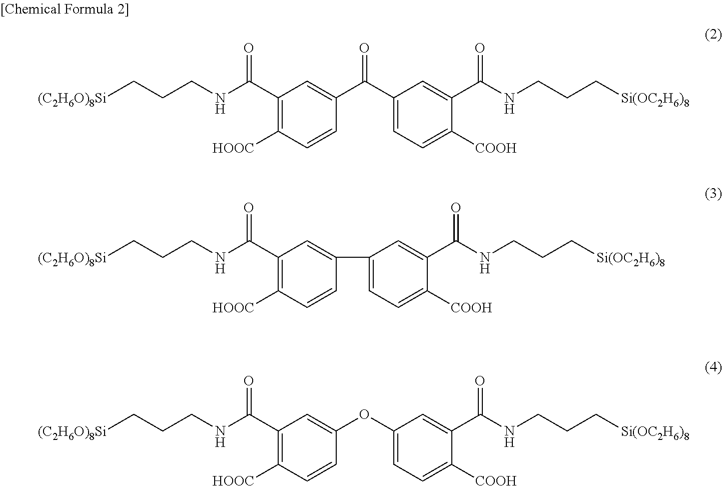

[4] The resin composition described in any of [1] to [3], wherein the polyimide precursor (a) has a structural unit represented by the following formula (5):

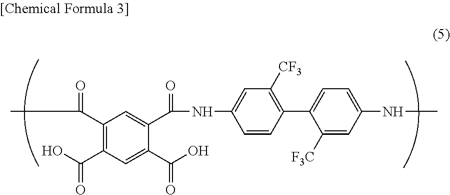

and a structural unit represented by the following formula (6).

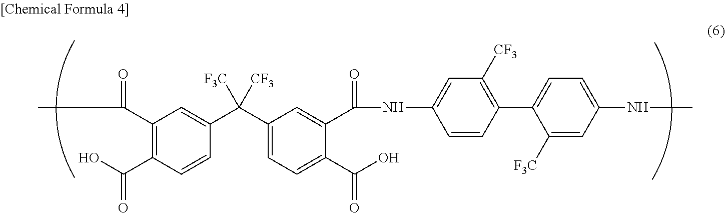

[5] The resin composition described in any of [1] to [4], wherein, in the polyimide precursor (a), the molar ratio of the structural unit represented by formula (5) to the structural unit represented by formula (6) is 90/10 to 50/50.

[6] A resin composition containing a polyimide precursor (a) and an organic solvent (b); wherein, the polyimide precursor (a) has a structural unit represented by the following formula (5):

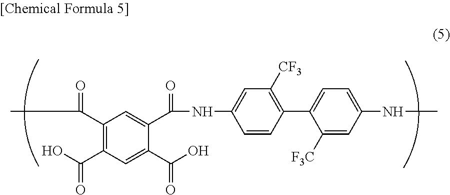

and a structural unit represented by the following formula (6):

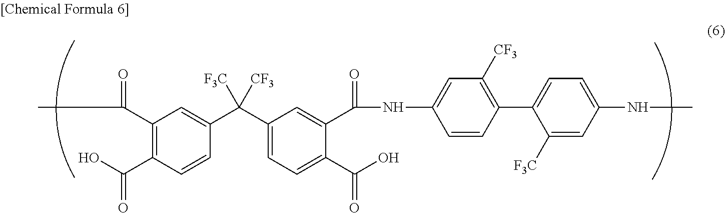

and the content of polyimide precursor having a molecular weight of less than 1,000 based on the total weight of the polyimide precursor (a) is less than 5% by weight.

[7] The resin composition described in [6], wherein the content of the polyimide precursor (a) having a molecular weight of less than 1,000 is less than 1% by weight.

[8] The resin composition described in [6] or [7], wherein, in the polyimide precursor (a), the molar ratio of the structural unit represented by formula (5) to the structural unit represented by formula (6) is 90/10 to 50/50.

[9] A resin composition containing a polyimide precursor (a) and an organic solvent (b); wherein, the polyimide precursor (a) is a mixture of a polyimide precursor having a structural unit represented by the following formula (5):

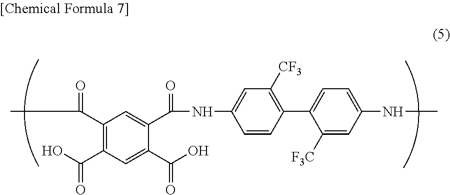

and a polyimide precursor having a structural unit represented by the following formula (6).

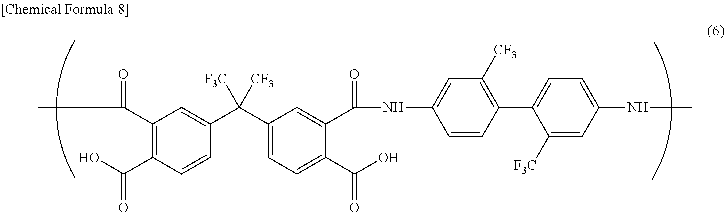

[10] The resin composition described in [9], wherein the weight ratio of the polyimide precursor having a structural unit represented by formula (5) to the polyimide precursor having a structural unit represented by formula (6) is 90/10 to 50/50.

[11] The resin composition described in any of [1] to [10], wherein the water content is 3000 ppm or less.

[12] The resin composition described in any of [1] to [11], wherein the organic solvent (b) is an organic solvent having a boiling point of 170° C. to 270° C.

[13] The resin composition described in any of [1] to [12], wherein the organic solvent (b) is an organic solvent having a vapor pressure at 20° C. of 250 Pa or lower.

[14] The resin composition described in [12] or [13], wherein the organic solvent (b) is at least one type of organic solvent selected from the group consisting of N-methyl-2-pyrrolidone, γ-butyrolactone and a compound represented by the following general formula (7):

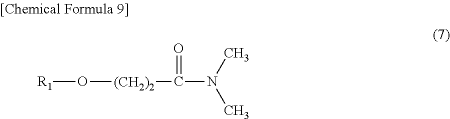

(wherein, R₁ represents a methyl group or n-butyl group).

[15] The resin composition described in any of [1] to [14], further containing a surfactant (c).

[16] The resin composition described in [15], wherein the surfactant (c) is one or more types of surfactants selected from the group consisting of fluorine-based surfactants and silicone-based surfactants.

[17] The resin composition described in [15], wherein the surfactant (c) is a silicone-based surfactant.

[18] The resin composition described in any of [6] to [17], further containing an alkoxysilane compound (d).

[19] A polyimide resin film obtained by heating the resin composition described in any of [1] to [18].

[20] A resin film containing the polyimide resin film described in [19].

[21] A method for producing a resin film, comprising:

a step for coating the resin composition described in any of [1] to [18] on the surface of a support,

a step for drying the coated resin composition and removing the solvent,

a step for heating the support and the resin composition to imidize a resin precursor contained in the resin composition and form a polyimide resin film, and

a step for detaching the polyimide resin film from the support.

[22] The method for producing a resin film described in [21], comprising a step for forming a release layer on the support prior to the step for coating the resin composition on the surface of the support.

[23] The method for producing a resin film described in [21], wherein the oxygen concentration in the heating step for forming a polyimide resin film is 2000 ppm or less.

[24] The method for producing a resin film described in [21], wherein the oxygen concentration in the heating step for forming a polyimide resin film is 100 ppm or less.

[25] The method for producing a resin film described in [21], wherein the oxygen concentration in the heating step for forming a polyimide resin film is 10 ppm or less.

[26] The method for producing a resin film described in [21], wherein the step for detaching the polyimide resin film from the support comprises a step for detaching the polyimide resin film after having irradiated with a laser from the side of the support.

[27] The method for producing a resin film described in [21], wherein the step for detaching the polyimide resin film having an element or circuit formed thereon from the support comprises a step for detaching the polyimide resin film from a composite containing the polyimide resin film, a release layer and the support.

[28] A laminate containing a support, and a cured product of the resin composition described in any of [6] to [19] in the form of a polyimide resin film.

[29] A method for producing a laminate, comprising:

a step for coating the resin composition described in any of [6] to [18] on the surface of a support, and

a step for heating the support and the resin composition to imidize the resin precursor contained in the resin composition and form a polyimide resin film.

[30] A method for producing a display substrate, comprising:

a step for coating the resin composition described in any of [6] to [18] on a support and heating to form a polyimide resin film,

a step for forming an element or circuit on the polyimide resin film, and

a step for detaching the polyimide resin film having an element or circuit formed thereon from the support.

[31] A display substrate formed according to the method for producing a display substrate described in [30].

[32] A laminate obtained by laminating the polyimide film described in [19], SiN and SiO₂ in that order.

### Effects of the Invention

The resin composition containing a polyimide precursor according to the present invention, in a first aspect thereof, has superior adhesiveness with a glass substrate (support) and does not generate particles during laser detachment.

Thus, in a first aspect thereof, a resin composition can be provided that has superior adhesiveness with a glass substrate (support) and does not generate particles during laser detachment.

In a second aspect thereof, the resin composition has superior storage stability and superior coatability. In addition, a polyimide resin film and resin film obtained from the composition have low residual stress, low yellow index (YI) value and have little effect of oxygen concentration during a curing step on YI value and total light transmittance.

Thus, in the present invention, a resin composition containing a polyimide precursor can be provided that has superior storage stability and superior coatability. In addition, the present invention is able to provide a polyimide resin film and resin film that has low residual stress, low yellow index (YI) value, little effect of oxygen concentration during a curing step on YI value and total light transmittance and little difference in refractive indices between the front and back sides, a production method thereof, a laminate and a production method thereof. Moreover, the present invention is able to provide a display substrate having little difference in refractive indices between the front and back sides and low yellow index value, and a production method thereof.

### BEST MODE FOR CARRYING OUT THE INVENTION

The following provides a detailed explanation of embodiments exemplifying the present invention (to be abbreviated as “embodiments”). Furthermore, the present invention is not limited to the following embodiments and can be altered and modified in various ways within the gist thereof. Furthermore, unless specifically indicated otherwise, the number of repetitions of structural units in the formulas of the present disclosure is merely intended to indicate the number of structural units that can be contained in the entire resin precursor, and it should therefore be noted that it is not intended to indicate a specific binding mode such as a block structure and the like. In addition, unless specifically indicated otherwise, the values of properties described in the present disclosure are intended to indicate values measured according to methods described in the section entitled “Examples” or methods understood by a person with ordinary skill in the art as being equivalent thereto.

<Resin Composition>

The resin composition provided by one aspect of the present invention contains a polyimide precursor (a), an organic solvent (b) and an alkoxysilane compound (d).

The following provides an explanation of each component.

[Polyimide Precursor (a)]

The polyimide precursor in a first aspect is a polyimide precursor in which the residual stress with a support when in the form of a polyimide is −5 MPa to 10 MPa. Here, residual stress can be measured according to the method described in the examples to be subsequently described.

Examples of the support in the first aspect include a glass substrate, silicon wafer and inorganic film.

Although there are no limitations on the polyimide precursor in the first aspect provided the residual stress thereof when in the form of a polyimide is −5 MPa to 10 MPa, it is preferably −3 MPa to 3 MPa from the viewpoint of warping following the formation of an inorganic film.

In addition, the yellow index is preferably 15 or less at a film thickness of 10 μm from the viewpoint of applying to a flexible display.

The following provides an explanation of the polyimide precursor that yields a polyimide having residual stress of −5 MPa to 10 MPa and a yellow index of 15 or less at a film thickness of 10 μm.

The polyimide precursor in the first aspect is preferably represented by the following general formula (8):

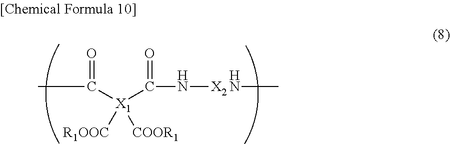

(wherein, in general formula (8) above, R₁ respectively and independently represents a hydrogen atom, monovalent aliphatic hydrocarbon having 1 to 20 carbon atoms or aromatic group having 6 to 10 carbon atoms,

X₁ represents a tetravalent organic group having 4 to 32 carbon atoms, and

X₂ represents a divalent organic group having 4 to 32 carbon atoms).

In the aforementioned resin precursor, general formula (8) is a structure obtained by reacting a tetracarboxylic dianhydride and a diamine. X₁ is derived from the tetracarboxylic dianhydride while X₂ is derived from the diamine.

X₂ in general formula (8) in the first aspect is preferably a residue derived from 2,2′-bis(trifluoromethyl)benzidine, 4,4-(diaminodiphenyl)sulfone or 3,3-(diaminodiphenyl)sulfone.

<Tetracarboxylic Dianhydride)

The following provides an explanation of the tetracarboxylic dianhydride that leads to the tetravalent organic group X₁ contained in the aforementioned general formula (8).

Specifically, the aforementioned tetracarboxylic dianhydride is preferably a compound selected from an aromatic tetracarboxylic dianhydride having 8 to 36 carbon atoms, an aliphatic tetracarboxylic dianhydride having 6 to 50 carbon atoms and an alicyclic tetracarboxylic dianhydride having 6 to 36 carbon atoms. Here, the number of carbon atoms includes the number of carbon atoms contained in the carboxyl groups.

More specifically, examples of aromatic tetracarboxylic dianhydrides having 8 to 36 carbon atoms include 4,4′-(hexafluoroisopropylidene)diphthalic anhydride (6FDA), 5-(2,5-dioxotetrahydro-3-furanyl)-3-methyl-cyclohexene-1,2-dicarboxylic anhydride, pyromellitic dianhydride (PMDA), 1,2,3,4-benzenetetracarboxylic dianhydride, 3,3′,4,4′-benzophenonetetracarboxylic dianhydride (BTDA), 2,2′,3,3′-benzophenonetetracarboxylic dianhydride, 3,3′,4,4′-biphenyltetracarboxylic dianhydride (BPDA), 3,3′4,4′-diphenylsulfonetetracarboxylic dianhydride (DSDA), 2,2′,3,3′-biphenyltetracarboxylic dianhydride, methylene-4,4′-diphthalic dianhydride, 1,1-ethylidene-4,4′-diphthalic dianhydride, 2,2-propylidene-4,4′-diphthalic dianhydride, 1,2-ethylene-4,4′-diphthalic dianhydride, 1,3-trimethylene-4,4′-diphthalic dianhydride, 1,4-tetramethylene-4,4′-diphthalic dianhydride, 1,5-pentamethylene-4,4′-diphthalic dianhydride, 4,4′-oxydiphthalic dianhydride (ODPA), 4,4′-biphenylbis(trimellitic monoester anhydride) (TAHQ), thio-4,4′-diphthalic dianhydride, sulfonyl-4,4′-diphthalic dianhydride, 1,3-bis(3,4-dicarboxyphenyl)benzene dianhydride, 1,3-bis(3,4-dicarboxyphenoxy)benzene dianhydride, 1,4-bis(3,4-dicarboxyphenoxy)benzene dianhydride, 1,3-bis[2-(3,4-dicarboxyphenyl)-2-propyl]benzene dianhydride, 1,4-bis[2-(3,4-dicarboxyphenyl)-2-propyl]benzene dianhydride, bis[3-(3,4-dicarboxyphenoxy)phenyl]methane dianhydride, bis[4-(3,4-dicarboxyphenoxy)phenyl]methane dianhydride, 2,2-bis[3-(3,4-dicarboxyphenoxy)phenyl]propane dianhydride, 2,2-bis[4-(3,4-dicarboxyphenoxy)phenyl]propane dianhydride (BPADA), bis(3,4-dicarboxyphenoxy)dimethylsilane dianhydride, 1,3-bis(3, 4-dicarboxyphenyl)-1,1,3,3-tetramethyldisiloxane dianhydride, 2,3,6,7-naphthalenetetracarboxylic dianhydride, 1,4,5,8-naphthalenetetracarboxylic dianhydride, 1,2,5,6-naphthalenetetracarboxylic dianhydride, 3,4,9,10-perylenetetracarboxylic dianhydride, 2,3,6,7-anthracenetetracarboxylic dianhydride and 1.2.7,8-phenanthracenetetracarboxylic dianhydride.

Examples of aliphatic tetracarboxylic dianhydrides having 6 to 50 carbon atoms include ethylenetetracarboxylic dianhydride and 1,2,3,4-butanetetracarboxylic dianhydride. Examples of alicyclic tetracarboxylic dianhydrides having 6 to 36 carbon atoms include 1,2,3,4-cyclobutanetetracarboxylic dianhydride (CBDA), cyclopentanetetracarboxylic dianhydride, cyclohexane-1,2,3,4-tetracarboxylic dianhydride, cyclohexane-1,2,4,5-tetracarboxylic dianhydride (CHDA), 3,3′,4,4′-bicyclohexyltetracarboxylic dianhydride, carbonyl-4,4′-bis(cyclohexane-1,2-dicarboxylic acid) dianhydride, methylene-4,4′-bis(cyclohexane-1,2-dicarboxylic acid) dianhydride, 1,2-ethylene-4,4′-bis(cyclohexane-1,2-dicarboxylic acid) dianhydride, 1,1-ethylidene-4,4′-bis(cyclohexane-1,2-dicarboxylic acid) dianhydride, 2,2-propylidene-4,4′-bis(cyclohexane-1,2-dicarboxylic acid) dianhydride, oxy-4,4′-bis(cyclohexane-1,2-dicarboxylic acid) dianhydride, thio-4,4′-bis(cyclohexane-1,2-dicarboxylic acid) dianhydride, sulfonyl-4,4′-bis(cyclohexane-1,2-dicarboxylic acid) dianhydride, bicycle[2,2,2]oct-7-ene-2,3,5,6-tetracarboxylic dianhydride, rel-[1S,5R,6R]-3-oxabicyclo[3,2,1]octane-2,4-dione-6-spiro-3′-(tetrahydrofuran-2′,5′-dione), 4-(2,5-dioxotetrahydrofuran-3-yl)-1,2,3,4-tetrahydronaphthalene-1,2-dicarboxylic anhydride and ethylene glycol-bis-(3,4-dicarboxylic anhydride phenyl) ether.

Among these, the use of one or more types of tetracarboxylic dianhydrides selected from the group consisting of BTDA, PMDA, BPDA and TAHQ is preferable from the viewpoints of reducing CTE, improving chemical resistance, improving glass transition temperature (Tg) and improving mechanical elongation. In addition, in the case of desiring to obtain a film having higher transparency, the use of one or more types of tetracarboxylic anhydrides selected from the group consisting of 6FDA, ODPA and BPADA is preferable from the viewpoints of reducing yellow index, decreasing birefringence and improving mechanical elongation. In addition, BPDA is preferable from the viewpoints of reducing residual stress, improving yellow index, decreasing birefringence, improving chemical resistance, improving Tg and improving mechanical elongation. In addition, CHDA is preferable from the viewpoints of reducing residual stress and reducing yellow index. Among these, the use of a combination of one or more types of tetracarboxylic dianhydrides selected from the group consisting of PMDA and BPDA, having a rigid structure that demonstrates high chemical resistance, high Tg and low CTE, and one or more types of tetracarboxylic dianhydrides selected from the group consisting of 6FDA, ODPA and CHDA, having low yellow index and low birefringence, is preferable from the viewpoints of high chemical resistance, reducing residual stress, reducing yellow index, decreasing birefringence and improving total light transmittance.

The resin precursor of the first aspect may also be a polyamide-imide precursor by using a dicarboxylic acid in addition to the aforementioned tetracarboxylic dianhydride within a range that does not impair the performance thereof. The use of such a precursor makes it possible to adjust various properties such as improvement of mechanical elongation, improvement of glass transition temperature or reduction of yellow index in the resulting film. Examples of this dicarboxylic acid include dicarboxylic acids having an aromatic ring and alicyclic dicarboxylic acids. At least one compound selected from the group consisting of aromatic dicarboxylic acids having 8 to 36 carbon atoms and alicyclic dicarboxylic acids having 6 to 34 carbon atoms is particularly preferable. The number of carbon atoms referred to here includes the number of carbon atoms contained in the carboxyl groups.

Among these, dicarboxylic acids having an aromatic ring are preferable.

Specific examples thereof include isophthalic acid, terephthalic acid, 4,4′-biphenyldicarboxylic acid, 3,4′-biphenyldicarboxylic acid, 3,3′-biphenyldicarboxylic acid, 1,4-naphthalenedicarboxylic acid, 2,3-naphthalenedicarboxylic acid, 1,5-naphthalenedicarboxylic acid, 2,6-naphthalenedicarboxylic acid, 4,4′-sulfonylbisbenzoic acid, 3,4′-sulfonylbisbenzoic acid, 3,3′-sulfonylbisbenzoic acid, 4,4′-oxybisbenzoic acid, 3,4′-oxybisbenzoic acid, 3,3′-oxybisbenzoic acid, 2,2-bis(4-carboxyphenyl)propane, 2,2-bis(3-carboxyphenyl)propane, 2,2′-dimethyl-4,4′-biphenyldicarboxylic acid, 3,3′-dimethyl-4,4′-biphenyldicarboxylic acid, 2,2′-dimethyl-3,3′-biphenyldicarboxylic acid, 9,9-bis(4-(4-carboxyphenoxy)phenyl)fluorene, 9, 9-bis(4-(3-carboxyphenoxy)phenyl)fluorene, 4,4′-bis(4-carboxyphenoxy)biphenyl, 4,4′-bis(3-carboxyphenoxy)biphenyl, 3,4′-bis(4-carboxyphenoxy)biphenyl, 3,4′-bis(3-carboxyphenoxy)biphenyl, 3,3′-bis(4-carboxyphenoxy)biphenyl, 3,3′-bis(3-carboxyphenoxy)biphenyl, 4,4′-bis(4-carboxyphenoxy)-p-terphenyl, 4,4′-bis(4-carboxyphenoxy)-m-terphenyl, 3,4′-bis(4-carboxyphenoxy)-p-terphenyl, 3,3′-bis(4-carboxyphenoxy)-p-terphenyl, 3,4′-bis(4-carboxyphenoxy)-m-terphenyl, 3,3′-bis(4-carboxyphenoxy)-m-terphenyl, 4,4′-bis(3-carboxyphenoxy)-p-terphenyl, 4,4′-bis(3-carboxyphenoxy)-m-terphenyl, 3,4′-bis(3-carboxyphenoxy)-p-terphenyl, 3,3′-bis(3-carboxyphenoxy)-p-terphenyl, 3,4′-bis(3-carboxyphenoxy)-m-terphenyl, 3,3′-bis(3-carboxyphenoxy)-m-terphenyl, 1,1-cyclobutanedicarboxylic acid, 1,4-cyclohexanedicarboxylic acid, 1,2-cyclohexanedicarboxylic acid, 4,4′-benzophenonedicarboxylic acid, 1,3-phenylenediacetic acid, 1,4-phenylenediacetic acid, and 5-aminoisophthalic acid derivatives and the like described in International Publication No. WO 2005/068535. In the case of actually copolymerizing these dicarboxylic acids into a polymer, they may be used in the form of an acid chloride derived from thionyl chloride or an active ester.

Among these, terephthalic acid is particularly preferable from the viewpoints of reducing YI value and improving Tg. In the case of using a dicarboxylic acid with a tetracarboxylic dianhydride, the dicarboxylic acid is preferably 50 mol % or less based on the total combined number of moles of the dicarboxylic acid and tetracarboxylic dianhydride from the viewpoint of chemical resistance of the resulting film.

<Diamine>

Specific examples of the diamine that leads to X₂ in the resin precursor according to the first aspect include 4,4-(diaminodiphenyl)sulfone (4,4-DAS), 3,4-(diaminodiphenyl)sulfone, 3,3-(diaminodiphenyl)sulfone (3,3-DAS), 2,2′-bis(trifluoromethyl)benzidine (TFMB), 2,2′-dimethyl-4,4′-diaminobiphenyl (m-TB), 1,4-diaminobenzene (p-PD), 1,3-diaminobenzene (m-PD), 4-aminophenyl-4′-aminobenzoate (APAB), 4,4′-diaminobenzoate (DABA), 4,4-(or 3,4′-, 3,3′- or 2,4′-)diaminodiphenyl ether, 4,4′-(or 3,3′-)diaminodiphenylsulfone, 4,4′-(or 3,3′-)-diaminodiphenylsulfide, 4,4′-benzophenonediamine, 3,3′-benzophenonediamine, 4,4′-di(4-aminophenoxy)phenylsulfone, 4,4′-di(3-aminophenoxy)phenylsulfone, 4,4′-bis(4-aminophenoxy)biphenyl, 1,4-bis(4-aminophenoxy)benzene, 1,3-bis(4-aminophenoxy)benzene, 2,2-bis{4-(4-aminophenoxy)phenyl}propane, 3,3′,5,5′-tetramethyl-4,4′-diaminodiphenylmethane, 2,2′-bis(4-aminophenyl)propane, 2,2′,6,6′-tetramethyl-4,4′-diaminobiphenyl, 2,2′,6,6′-tetratrifluoromethyl-4,4′-diaminobiphenyl, bis{(4-aminophenyl)-2-propyl}1,4-benzene, 9,9-bis(4-aminophenyl)fluorene, 9,9-bis(4-aminophenoxyphenyl)fluorene, 3,3′-dimethylbenzidine, 3,3-dimethoxybenzidine, 3,5-diamine benzoic acid, 2,6-diaminopyridine, 2,4-diaminopyridine, bis(4-aminophenyl-2-propyl)-1,4-benzene, 3,3′-bis(trifluoromethyl)-4,4′-diaminobiphenyl (3,3′-TFDB), 2,2′-bis[3(3-aminophenoxy)phenyl]hexafluoropropane (3-BDAF), 2,2′-bis[4(4-aminophenoxy)phenyl]hexafluoropropane (4-BDAF), 2,2′-bis(3-aminophenyl)hexafluoropropane (3,3′-6F) and 2,2′-bis(4-aminophenyl)hexafluoropropane (4,4′-6F). Among these, the use of one or more types of diamines selected from the group consisting of 4,4-DAS, 3,3-DAS, 1,4-cyclohexanediamine, TFMB and APAB is preferable from the viewpoints of reducing yellow index, decreasing CTE and high Tg.

The number average molecular weight of the resin precursor according to the first aspect is preferably 3,000 to 1,000,000, more preferably 5,000 to 500,000, even more preferably 7,000 to 300,000 and particularly preferably 10,000 to 250,000. A number average molecular weight of 3,000 or more is preferable from the viewpoint of obtaining favorable heat resistance and strength (e.g. stretch), and a number average molecular weight of 1,000,000 or less is preferable from the viewpoint of obtaining favorable solubility in solvent and enabling coating at a desired film thickness without causing bleeding during processing such as coating. The number average molecular weight is preferably 50,000 or more from the viewpoint of obtaining high mechanical elongation. In the present disclosure, the aforementioned number average molecular weight is a value determined by calculating as polystyrene using gel permeation chromatography.

A portion of the resin precursor according to the first aspect may also be imidized. Imidization of the resin precursor can be carried out by known chemical imidization or thermal imidization. Among these, thermal imidization is preferable. A specific technique for carrying out imidization consists of preparing a resin composition according to a method to be subsequently described followed by heating the solution at 130° C. to 200° C. for 5 minutes to 2 hours. According to this method, a portion of the polymer can be dehydrated and imidized to a degree that does not cause precipitation of the resin precursor. Here, imidization rate can be controlled by controlling the heating temperature and heating time. Partial imidization makes it possible to improve viscosity stability when storing the resin composition at room temperature. The range of the imidization rate is preferably 50% to 70% from the viewpoints of solubility in solution and storage stability.

In addition, a portion or all of the carboxylic acid may be esterified by adding N,N-dimethylformamide dimethyl acetal or N,N-dimethylformamide diethyl acetal and the like to the aforementioned resin precursor followed by heating. As a result thereof, viscosity stability of the resin composition when storing at room temperature can be improved.

The organic solvent (b) of the first aspect is the same as the organic acid (b) in the second aspect to be subsequently described.

<Alkoxysilane Compound (d)>

Next, an explanation is provided of the alkoxysilane compound (d) according to the first aspect.

Optical absorbance at 308 nm of the alkoxysilane compound according to the first aspect is 0.1 to 0.5 at a solution thickness of 1 cm when in the form of a 0.001% by weight NMP solution. There are no particular limitations on the structure thereof provided this requirement is satisfied. As a result of making optical absorbance to be within this range, the resulting resin film can be easily subjected to laser detachment while retaining high transparency.

The aforementioned alkoxysilane compound can be synthesized by, for example:

a reaction between an acid dianhydride and a trialkoxysilane compound,

a reaction between an acid anhydride and a trialkoxysilane compound, or

a reaction between an amino compound and an isocyanatotrialkoxysilane compound. The aforementioned acid dianhydride, acid anhydride and amino compound preferably each have an aromatic ring (and particularly, a benzene ring).

The alkoxysilane compound according to the first aspect is preferably a compound obtained by reacting an aminotrialkoxysilane compound with an acid dianhydride represented by the following general formula (1):

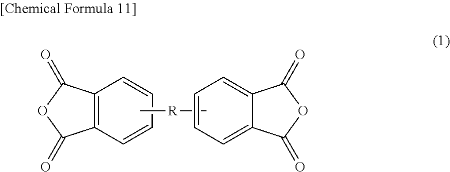

(wherein, R represents a single bond, oxygen atom, sulfur atom or alkylene group having 1 to 5 carbon atoms) from the viewpoint of adhesiveness.

The aforementioned reaction between an acid dianhydride and aminotrialkoxysilane in the first aspect can be carried out by, for example, adding 1 mole of acid dianhydride to a solution obtained by dissolving 2 moles of aminotrialkoxysilane in a suitable solvent, and reacting at a reaction temperature of preferably 0° C. to 50° C. and for a reaction time of preferably 0.5 hours to 8 hours.

Although there are no particular limitations on the aforementioned solvent provided it dissolves the raw material compounds and products, preferable examples thereof include N-methyl-2-pyrrolidone, γ-butyrolactone, Ekuamido M100 (trade name, Idemitsu Retail Marketing Co., Ltd.) and Ekuamido B100 (trade name, Idemitsu Retail Marketing Co., Ltd.) from the viewpoint of compatibility with the aforementioned polyamide precursor (a).

The alkoxysilane compound according to the first aspect is preferably at least one type of alkoxysilane compound selected from the group consisting of compounds respectively represented by the following general formulas (2) to (4):

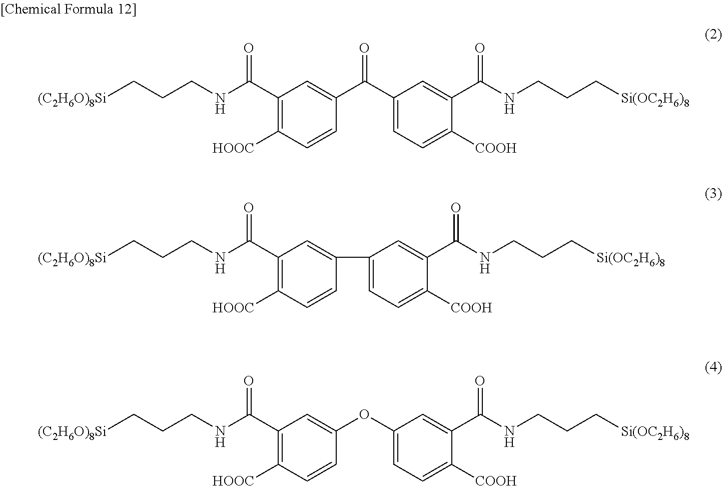

from the viewpoints of transparency, adhesiveness and detachability.

The content of the alkoxysilane compound (d) in the resin composition according to the first aspect can be suitably designed within a range over which adequate adhesiveness and detachability are demonstrated. An example of a preferable range thereof is a range of 0.01% by weight to 20% by weight of the alkoxysilane compound (d) based on 100% by weight of the polyimide precursor (a).

As a result of making the content of the alkoxysilane compound (d) to be 0.01% by weight or more based on 100% by weight of the polyimide precursor (a), favorable adhesiveness with the support can be obtained for the resulting resin film. The content of the alkoxysilane compound (d) is preferably 20% by weight or less from the viewpoint of storage stability of the resin composition. The content of the alkoxysilane compound (d) is more preferably 0.02% by weight to 15% by weight, even more preferably 0.05% by weight to 10% by weight, and particularly preferably 0.1% by weight to 8% by weight based on the weight of the polyimide precursor (a).

<Resin Composition>

The resin composition provided by a second aspect of the present invention contains a polyimide precursor (a) and an organic solvent (b). The following provides an explanation of each component in that order.

[Polyimide Precursor (a)]

The polyimide precursor in the present embodiment is a copolymer having a structural unit represented by the following formula (5) and formula (6), or is a mixture of a polyimide precursor having a structural unit represented by the formula (5) and a polyimide precursor having a structural unit represented by the formula (6). The content of the polyimide precursor in the present embodiment having a molecular weight of less than 1,000 is less than 5% by weight based on the total weight of the aforementioned polyimide precursor (a).

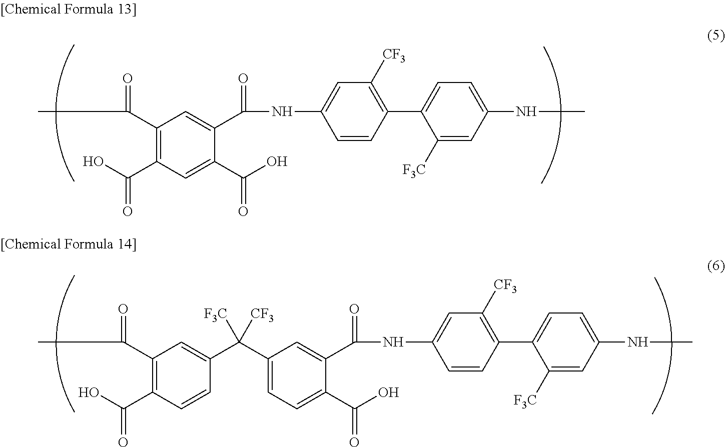

Here, the ratio (molar ratio) of structural units (5) and (6) of the aforementioned copolymer is such that ratio of (5):(6) is preferably 95:5 to 40:60 from the viewpoints of coefficient of thermal expansion (CTE), residual stress and yellow index (YI) of the resulting cured product. In addition, the ratio of (5):(6) is more preferably 90:10 to 50:50 from the viewpoint of YI, and even more preferably 95:5 to 50:50 from the viewpoint of residual stress. The aforementioned ratio of (5) to (6) can be determined from the results of the ¹H-NMR spectrum thereof. In addition, the copolymer may be a block copolymer or random copolymer.

In addition, the weight ratio of a polyimide precursor having a structural unit represented by the aforementioned formula (5) and a polyimide precursor having a structural unit represented by the aforementioned formula (6) in a mixture of the aforementioned polyimide precursors is such that the ratio of (5):(6) is preferably 95:5 to 40:60 from the viewpoints of CTE and residual stress of the resulting cured product, and more preferably 95:5 to 50:50 from the viewpoint of CTE.

The polyimide precursor (copolymer) of the present invention can be obtained by polymerizing pyromellitic dianhydride (PMDA), 4,4′-(hexafluoroisopropylidene)diphthalic anhydride (6FDA) and 2,2′-bis(trifluoromethyl)benzidine (TFMB). Namely, structural unit (5) is formed by polymerizing PMDA and TFMB, while structural unit (6) is formed by polymerizing 6FDA and TFMB.

As a result of using PMDA, it is thought that the resulting cured product is able to demonstrate favorable heat resistance and residual stress can be decreased.

As a result of using 6FDA, it is thought that the resulting cured product is able to demonstrate favorable transparency, transparency becomes high and YI is able to be decreased.

Furthermore, although an ordinary acid anhydride is used for the aforementioned raw material tetracarboxylic acids (PMDA, 6FDA), these acids and other derivatives thereof can also be used.

In addition, as a result of using TFMB, it is thought that the resulting cured product is able to demonstrate favorable heat resistance and transparency.

The aforementioned ratio of the structural units (5) and (6) can be adjusted by changing the ratio of the tetracarboxylic acids of PMDA and 6FDA.

The polyimide precursor (mixture) of the present invention can be obtained by mixing a polymer consisting of PMDA and TFMB and a polymer consisting of 6FDA and TFMB. Namely, polymer consisting of PMDA and TFMB has the structural unit (5) and the polymer consisting of 6FDA and TFMB has the structural unit (6).

In the polyimide precursor (copolymer) according to the present embodiment, the total weight of the aforementioned structural units (5) and (6) based on the total weight of the resin is preferably 30% by weight or more from the viewpoints of low CTE and low residual stress, and more preferably 70% by weight or more from the viewpoint of low CTE. The total weight of the structural units (5) and (6) is most preferably 100% by weight.

In addition, the resin precursor according to the present embodiment may further contain a structural unit (8) having a structure represented by the following general formula (8) as necessary within a range that does not impair performance.

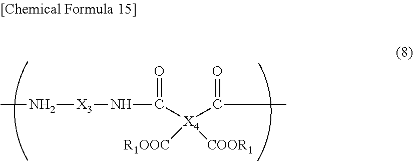

(In the formula, R₁ respectively and independently represents a hydrogen atom, monovalent aliphatic hydrocarbon or monovalent aromatic hydrocarbon having 1 to 20 carbon atoms, and a plurality of R₁ may be present. X₃ respectively and independently represents a divalent organic group having 4 to 32 carbon atoms and a plurality of X₃ may be present. X₄ respectively and independently represents a tetravalent organic group having 4 to 32 carbon atoms, and t represents an integer of 1 to 100.)

The structural unit (8) has a structure other than a polyimide precursor in which the acid dianhydride is derived from PMDA and/or 6FDA and the diamine is derived from TFMB.

In the structural unit (8), R₁ is preferably a hydrogen atom. In addition, X₃ is preferably a divalent aromatic group or alicyclic group from the viewpoints of total light transmittance and decreasing the YI value. In addition, X₄ is preferably a divalent aromatic group or alicyclic group from the viewpoints of total light transmittance and decreasing YI value. The organic groups X₁, X₂ and X₄ may be mutually the same or different.

The weight ratio of the structural unit (8) in the resin precursor according to the present embodiment is 80% by weight or less and preferably 70% by weight or less of the entire resin structure from the viewpoints of decreasing the dependency of YI value and total light transmittance on oxygen.

The molecular weight of the polyamide acid (polyamide precursor) of the present invention in terms of the weight average molecular weight is preferably 10,000 to 500,000, more preferably 10,000 to 300,000 and particularly preferably 20,000 to 200,000. If the weight average molecular weight is lower than 10,000, cracks may form in the resin film in the step for heating the coated resin composition, and even if the resin film is able to be formed, there is the risk of a lack of favorable mechanical properties. If the weight average molecular weight exceeds 500,000, it becomes difficult to control the weight average molecular weight when synthesizing the polyamide acid, and there is also the risk of it being difficult to obtain a resin composition of suitable viscosity. In the present disclosure, weight average molecular weight is the value determined as polystyrene using gel permeation chromatography.

In addition, the number average molecular weight of the polyimide resin precursor according to the present embodiment is preferably 3,000 to 1,000,000, more preferably 5,000 to 500,000, even more preferably 7,000 to 300,000 and particularly preferably 10,000 to 250,000. The number average molecular weight is preferably 3,000 or more from the viewpoints of obtaining favorable heat resistance and strength (e.g. stretch), while the number average molecular weight is preferably 1,000,000 or less from the viewpoints of obtaining favorable solubility in solvent and enabling coating at a desired film thickness without causing bleeding during processing such as coating. From the viewpoint of obtaining high mechanical elongation, the number average molecular weight is preferably 50,000 or more. In the present disclosure, number average molecular weight is the value determined as polystyrene using gel permeation chromatography.

In a preferable aspect, the resin precursor may be partially imidized.

The content of polyimide precursor having a molecular weight of less than 1,000 based on the total amount of polyimide precursor can be measured by gel permeation chromatography (GPC) using a solution in which the polyimide precursor is dissolved and then calculated from the peak area of the resulting chromatogram.

Residual molecules having a molecular weight of less than 1,000 are thought to involve the water content of the solvent used during synthesis. Namely, a portion of the acid anhydride groups of the acid dianhydride monomer are thought to undergo hydrolysis resulting in the formation of carboxyl groups, thereby remaining in a low molecular weight state without increasing in molecular weight.

The water content of the solvent is thought to involve the grade of the solvent used (dehydrated grade or general-purpose grade), the solvent container (such as a bottle, 18 L drum or canister), the manner in which the solvent is stored (such as in the absence of a rare gas infusion agent), or amount of time from opening of the solvent container until use (such as whether the solvent is used immediately after opening the container or used after a certain amount of time has elapsed after having opened the container). In addition, replacement of the inside of the reactor with a rare gas prior to synthesis and the presence or absence of the inflow of rare gas during synthesis are also thought to be involved.

The content of polyimide precursor molecules having a molecular weight of less than 1,000 is preferably less than 5% and more preferably less than 1% based on the total amount of polyimide precursor from the viewpoints of the residual stress of a polyimide resin film obtained by curing a resin composition that uses the polyimide precursor and the haze value of an inorganic film formed on the polyimide resin film.

Although the reason why these parameters are favorable is uncertain in the case the content of molecules having a molecular weight of less than 1,000 is within the aforementioned ranges, low molecular weight components are thought to be involved.

The water content of the resin composition of the present embodiment is characterized as being 3,000 ppm or less.

The water content of the resin composition is preferably 3,000 ppm or less, more preferably 1,000 ppm or less and even more preferably 500 ppm or less from the viewpoint of viscosity stability when storing the resin composition.

Although the reason why this parameter is favorable is uncertain in the case the water content of the resin composition is within the aforementioned ranges, water is thought to be involved in decomposition and reassembly of the polyimide precursor.

Since the resin precursor of the present embodiment is able to form a polyimide resin so that residual stress is 20 MPa or less at a film thickness of 10 μm, it is easily applied to a display production process provided with a TFT element device on a colorless and transparent polyimide substrate.

In addition, in a preferable aspect thereof, the resin precursor has the properties indicated below.

Yellow index at film thickness of 15 μm in a resin obtained by dissolving a the resin precursor in a solvent (such as N-methyl-2-pyrrolidone) and coating the resulting solution onto the surface of a support followed by heating the solution to 300° C. to 550° C. (e.g. 380° C.) in a nitrogen atmosphere (for 1 hour, for example) to imidize the resin precursor is 14 or less.

Residual stress in a resin obtained by dissolving the resin precursor in a solvent (such as N-methyl-2-pyrrolidone) and coating the resulting solution onto the surface of a support followed by heating the solution to 300° C. to 500° C. (e.g. 380° C.) in a nitrogen atmosphere (having, for example, an oxygen concentration of 2,000 ppm or less) to imidize the resin precursor is 25 MPa or less.

<Production of Resin Precursor>

The polyimide precursor (polyamide acid) of the present invention can be synthesized by a conventionally known synthesis method. For example, after having dissolved a prescribed amount of TFMB in a solvent, PMDA and 6FDA are respectively added in prescribed amounts to the resulting diamine solution and stirred.

When dissolving each of the monomer components, the components may be heated as necessary. The reaction temperature is preferably −30° C. to 200° C., more preferably 20° C. to 180° C. and particularly preferably 30° C. to 100° C. The endpoint of the reaction is taken to be the time when the desired molecular weight is reached as determined by GPC after continuing to stir at room temperature (20° C. to 25° C.) or a suitable reaction temperature. The aforementioned reaction can normally be completed in 3 hours to 100 hours.

In addition, the viscosity stability of the solution containing the resin precursor and solvent can be improved when storing at room temperature by esterifying all or a portion of the carboxylic acid by adding N,N-dimethylformamide dimethyl acetal or N,N-dimethylformamide diethyl acetal to the polyamide acid and heating as previously described. This ester-modified polyamide acid can also be obtained by a condensation reaction with diamine after preliminarily reacting the aforementioned tetracarboxylic anhydride with one equivalent of a monovalent alcohol based on the acid anhydride groups, and reacting with a dehydration condensing agent such as thionyl chloride or dicyclohexylcarbodiimide.

There are no particular limitations on the aforementioned reaction solvent provided it is a solvent that is able to dissolve diamines, tetracarboxylic acids and the resulting polyamide acid. Specific examples of such solvents include aprotic solvents, phenol-based solvents, ether and glycol-based solvents.

More specifically, examples of aprotic solvents include amide-based solvents such as N,N-dimethylformamide (DMF), N,N-dimethylacetoamide (DMAc), N-methyl-2-pyrrolidone (NMP), N-methylcaprolactam, 1,3-dimethylimidazolidinone, tetramethyl urea or Ekuamido M100 (trade name, Idemitsu Kosan Co., Ltd.) or Ekuamido B100 (trade name, Idemitsu Kosan Co., Ltd.) represented by the following general formula (7):

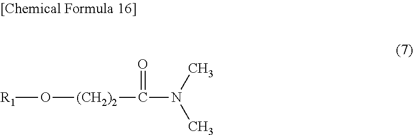

(M100: R₁ represents a methyl group, B100: R₁ represents an n-butyl group), lactone-based solvents such as γ-butyrolactone or γ-valerolactone, phosphorous-containing amide-based solvents such as hexamethylphosphoric amide or hexamethylphosphine triamide, sulfur-containing solvents such as dimethylsulfone, dimethylsulfoxide or sulfolane, ketone-based solvents such as cyclohexanone or methylcyclohexanone, tertiary amine-based solvents such as picoline or pyridine and ester-based solvents such as (2-methoxy-1-methylethyl) acetate. Examples of phenol-based solvents include phenol, o-cresol, m-cresol, p-cresol, 2,3-xylenol, 2,4-xylenol, 2,5-xylenol, 2,6-xylenol, 3,4-xylenol and 3,5-xylenol. Examples of ether-based and glycol-based solvents include 1,2-dimethoxyethane, bis(2-methoxyethyl) ether, 1,2-bis(2-methoxyethoxy) ethane, bis[2-(2-methoxyethoxy)ethyl]ether, tetrahydrofuran and 1,4-dioxane.

Among these, the boiling point at normal pressure is preferably 60° C. to 300° C., preferably 140° C. to 280° C. and particularly preferably 170° C. to 270° C. If the boiling point is higher than 300° C., an excessive amount of time is required in the drying step, while if the boiling point is lower than 60° C., the surface of the resin film becomes roughened in the drying step or air bubbles may enter the resin film, thereby resulting in the possibility of preventing the obtaining of a uniform film. In this manner, an organic solvent boiling point of 170° C. to 270° C. and a vapor pressure at 20° C. of 250 Pa or lower are preferable from the viewpoints of solubility and edge cissing during coating. Specific examples of such reaction solvents include N-methyl-2-pyrrolidone, γ-butyrolactone and the aforementioned Ekuamido M100 and Ekuamido B100. These reaction solvents may be used alone or as a mixture of two or more types.

The polyimide precursor (polyamide acid) of the present invention is normally obtained in the form of a solution using a reaction solvent described above for the solvent (to also be referred to as a polyamide acid solution). The ratio of the polyamide acid component (resin non-volatile component: to be referred to as the solute) based on the total amount of the resulting polyamide acid solution is preferably 5% by weight to 60% by weight, more preferably 10% by weight to 50% by weight and particularly preferably 10% by weight to 40% by weight from the viewpoint of coated film formability.

The solution viscosity of the aforementioned polyamide acid solution at 25° C. is preferably 500 mPa·s to 200,000 mPa·s, more preferably 2,000 mPa·s to 100,000 mPa·s and particularly preferably 3,000 mPa·s to 30,000 mPa·s. Solution viscosity can be measured using an E-type viscometer (Visconice HD manufactured by Toki Sangyo Co., Ltd.). If solution viscosity is lower than 300 mPa·s, coating becomes difficult during film formation, while if solution viscosity exceeds 200,000 mPa·s, there is the risk of the problem of difficulty in stirring during synthesis. However, even if the solution reaches a high viscosity when synthesizing the polyamide acid, a polyamide acid solution having a viscosity that facilitates handling can be obtained by adding a solvent following completion of the reaction and stirring. The polyimide of the present invention is obtained by heating the aforementioned polyimide precursor causing it to undergo dehydration ring closure.

<Resin Composition>

Another aspect of the present invention provides a resin composition containing the previously described polyimide precursor (a) and the organic solvent (b). This resin composition is typically a varnish.

[Organic Solvent (b)]

There are no particular limitations on the organic solvent (b) provided it is able to dissolve the polyimide precursor (polyamide acid) of the present invention, and a solvent able to be used when synthesizing the aforementioned polyimide precursor (a) can be used for the organic solvent (b). The organic solvent (b) may be the same or different from the solvent used when synthesizing the polyamide acid (a).

The amount of component (b) is preferably an amount at which the solid content concentration of the resin composition becomes 3% by weight to 50% by weight. Component (b) is preferably added so as to adjust the viscosity (25° C.) of the resin composition to 500 mPa·s to 100,000 mPa·s.

The resin composition according to the present embodiment has superior storage stability at room temperature, and the rate of change in viscosity of the varnish in the case of having stored for 2 weeks at room temperature is 10% or less relative to the initial viscosity. As a result, storage stability at room temperature is superior, frozen storage is not required, and handling becomes easy.

[Other Components]

The resin composition of the present invention may also contain an alkoxysilane compound, surfactant or leveling agent and the like in addition to the aforementioned components (a) and (b).

(Alkoxysilane Compound) The resin composition according to the present embodiment can contain 0.01% by weight to 20% by weight of an alkoxysilane compound based on 100% by weight of the polyimide precursor in order to ensure the polyimide obtained from the resin composition that have adequate adhesiveness with the support in the production process of a flexible device and the like.

Favorable adhesiveness with the support can be obtained by making the content of the alkoxysilane compound to be 0.01% by weight or more based on 100% by weight of the polyimide precursor. In addition, making the content of the alkoxysilane compound to be 20% by weight or less is preferable from the viewpoint of storage stability of the resin composition. The content of the alkoxysilane compound is more preferably 0.02% by weight to 15% by weight, even more preferably 0.05% by weight to 10% by weight and particularly preferably 0.1% by weight to 8% by weight based on the polyimide precursor.

The use of an alkoxysilane compound as an additive of the resin composition according to the present embodiment makes it possible to improve coatability (inhibit streaking) of the resin composition and lower the dependency on oxygen concentration of the YI value of the resulting cured film during curing.

Examples of alkoxysilane compounds include, but are not limited to, 3-mercaptopropyltrimethoxysilane (trade name: KBM803 manufactured by Shin-Etsu Chemical Co., Ltd. or trade name: Sila-Ace S810 manufactured by Chisso Corp.), 3-mercaptopropyltriethoxysilane (trade name: SIM6475.0 manufactured by Azmax Corp.), 3-mercaptopropylmethyldimethoxysilane (trade name: LS1375 manufactured by Shin-Etsu Chemical Co., Ltd. or trade name: SIM6474.0 manufactured by Azmax Corp.), mercaptomethyltrimethoxysilane (trade name: SIM6473.5C manufactured by Azmax Corp.), mercaptomethylmethyldimethoxysilane (trade name: SIM6473.0 manufactured by Azmax Corp.), 3-mercaptopropyldiethoxymethoxysilane, 3-mercaptopropylethoxydimethoxysilane, 3-mercaptopropyltripropoxysilane, 3-mercaptopropyldiethoxypropoxysilane, 3-mercaptopropylethoxydipropoxysilane, 3-mercaptopropyldimethoxypropoxysilane, 3-mercaptopropylmethoxydipropoxysilane, 2-mercaptoethyltrimethoxysilane, 2-mercaptoethyldiethoxymethoxysilane, 2-mercaptoethylethoxydimethoxysilane, 2-mercaptoethyltripropoxysilane, 2-mercaptoethyltripropoxysilane, 2-mercaptoethylethoxydipropoxysilane, 2-mercaptoethyldimethoxypropoxysilane, 2-mercaptoethylmethoxydipropoxysilane, 4-mercaptobutyltrimethoxysilane, 4-mercaptobutyltriethoxysilane, 4-mercaptobutyltripropoxysilane, N-(3-triethoxysilylpropyl) urea (trade name: LS3610 manufactured by Shin-Etsu Chemical Co., Ltd. or trade name: SIU9055.0 manufactured by Azmax Corp.), N-(3-trimethoxysilylpropyl) urea (trade name: SIU9058.0 manufactured by Azmax Corp.), N-(3-diethoxymethoxysilylpropyl) urea, N-(3-ethoxydimethoxysilylpropyl) urea, N-(3-tripropoxysilylpropyl) urea, N-(3-diethoxypropoxysilylpropyl) urea, N-(3-ethoxydipropoxysilylpropyl) urea, N-(3-dimethoxypropoxysilylpropyl) urea, N-(3-methoxydipropoxysilylpropyl) urea, N-(3-trimethoxysilylethyl) urea, N-(3-ethoxydimethoxysilylethyl) urea, N-(3-tripropoxysilylethyl) urea, N-(3-tripropoxysilylethyl) urea, N-(3-ethoxydipropoxysilylethyl) urea, N-(3-dimethoxypropoxysilylethyl) urea, N-(3-methoxydipropoxysilylethyl) urea, N-(3-trimethoxysilylbutyl) urea, N-(3-triethoxysilylbutyl) urea, N-(3-tripropoxysilylbutyl) urea, 3-(m-aminophenoxy) propyltrimethoxysilane (trade name: SLA0598.0 manufactured by Azmax Corp.), m-aminophenyltrimethoxysilane (trade name: SLA0599.0 manufactured by Azmax Corp.), p-aminophenyltrimethoxysilane (trade name: SLA0599.1 manufactured by Azmax Corp.), aminophenyltrimethoxysilane (trade name: SLA0599.2 manufactured by Azmax Corp.), 2-(trimethoxysilylethyl) pyridine (trade name: SIT8396.0 manufactured by Azmax Corp.), 2-(triethoxysilylethyl) pyridine, 2-(dimethoxysilylmethylethyl) pyridine, 2-(diethoxysilylmethylethyl) pyridine, (3-triethoxysilylpropyl)-t-butylcarbamate, (3-glycidoxypropyl)triethoxysilane, tetramethoxysilane, tetraethoxysilane, tetra-n-propoxysilane, tetra-i-propoxysilane, tetra-n-butoxysilane, tetra-i-butoxysilane, tetra-t-butoxysilane, tetrakis(methoxyethoxysilane), tetrakis(methoxy-n-propoxysilane), tetrakis(ethoxyethoxysilane), tetrakis(methoxyethoxyethoxysilane), bis(trimethoxysilyl) ethane, bis(trimethoxysilyl) hexane, bis(triethoxysilyl) methane, bis(triethoxysilyl) ethane, bis(triethoxysilyl) ethylene, bis(triethoxysilyl) octane, bis(triethoxysilyl) octadiene, bis[3-(triethoxysilyl)propyl] disulfide, bis[3-(triethoxysilyl)propyl] tetrasulfide, di-t-butoxydiacetoxysilane, di-i-butoxyaluminoxytriethoxysilane, bis(pentadionate)titanium-o,o′-bis(oxyethyl)-aminopropyltriethoxysilane, phenylsilane triol, methylphenylsilane diol, ethylphenylsilane diol, n-propylphenylsilane diol, isopropylphenylsilane diol, n-butylphenylsilane diol, isobutylphenylsilane diol, tert-butylphenylsilane diol, diphenylsilane diol, dimethoxydiphenylsilane, diethoxydiphenylsilane, dimethoxydi-p-tolylsilane, ethylmethylphenyl silanol, n-propylmethylphenyl silanol, isopropylmethylphenyl silanol, n-butylmethylphenyl silanol, isobutylmethylphenyl silanol, tert-butylmethylphenyl silanol, ethyl-n-propylphenyl silanol, ethylisopropylphenyl silanol, n-butylethylphenyl silanol, isobutylethylphenyl silanol, tert-butylethylphenyl silanol, methyldiphenyl silanol, ethyldiphenyl silanol, n-propyldiphenyl silanol, isopropyldiphenyl silanol, n-butyldiphenyl silanol, isobutyldiphenyl silanol, tert-butyldiphenyl silanol, triphenyl silanol, 3-ureidopropyltriethoxysilane, bis (2-hydroxyethyl)-3-aminopropyltriethoxysilane, 3-glycidoxypropyltrimethoxysilane, phenyltrimethoxysilane, γ-aminopropyltriethoxysilane, γ-aminopropyltrimethoxysilane, γ-aminopropyltripropoxysilane, γ-aminopropyltributoxysilane, γ-aminoethyltriethoxysilane, γ-aminoethyltrimethoxysilane, γ-aminoethyltripropoxysilane, γ-aminoethyltributoxysilane, γ-aminobutyltriethoxysilane, γ-aminobutyltrimethoxysilane, γ-aminobutyltripropoxysilane and γ-aminobutyltributoxysilane. These alkoxysilane compounds may be used alone or a plurality of types may be used in combination.

These alkoxysilane compounds are preferable from the viewpoints of the effect on coatability (inhibition of streaking) of the resin composition and on dependency on oxygen concentration of YI value and total light transmittance during the curing step, and among the aforementioned alkoxysilane compounds, one or more types selected from phenylsilane triol, trimethoxyphenylsilane, trimethoxy(p-tolyl)silane, diphenylsilane diol, dimethoxydiphenylsilane, diethoxydiphenylsilane, dimethoxy-di-p-tolylsilane, triphenyl silanol and alkoxysilane compounds represented by each of the following structures are preferable.

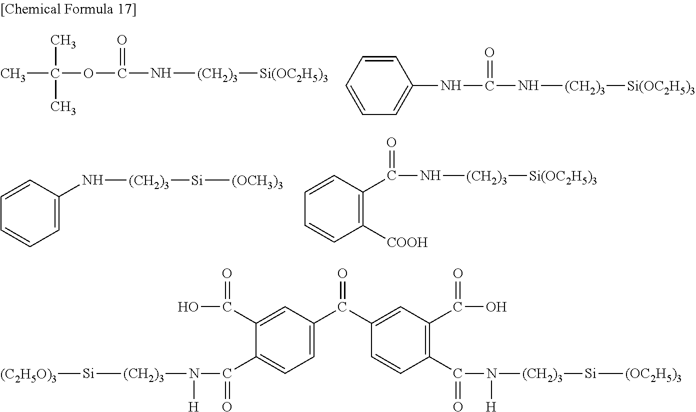

(Surfactant or Leveling Agent)

In addition, coatability can be improved by adding a surfactant or leveling agent to the resin composition. More specifically, the formation of streaks after coating can be prevented.

Examples of such surfactants or leveling agents include silicone-based surfactants such as organosiloxane polymers KF-640, KF-642, KF-643, KP-341, X-70-092, X-70-093, KBM303, KBM403, KBM803 (trade names, Shin-Etsu Chemical Co., Ltd.), SH-28PA, SH-190, SH-193, SZ-6032, SF-8428, DC-57, DC-190 (trade names, Dow Corning Toray Silicone Co., Ltd.), Silwet, L-77, L-7001, FZ-2105, FZ-2120, FZ-2154, FZ-2164, FZ-2166, L-7604 (trade names, Nippon Unicar Co., Ltd.), DBE-814, DBE-224, DBE-621, CMS-626, CMS-222, KF-352A, KF-354L, KF-355A, KF-6020, DBE-821, DBE-712 (trade names, Gelest Inc.), BYK-307, BYK-310, BYK-378, BYK-333 (trade names, Byk Chemie Japan K.K.) or Granol (trade name, Kyoeisha Chemical Co., Ltd.), examples of fluorine-based surfactants include Megaface F171, F173, R-08 (trade names, DIC Corp.), Fluorad FC4430 and FC4432 (Sumitomo 3M, Ltd.), and examples of nonionic surfactants include polyoxyethylene lauryl ether, polyoxyethylene stearyl ether, polyoxyethylene oleyl ether and polyoxyethylene octyl phenol ether.

Among these surfactants, silicone-based surfactants and fluorine-based surfactants are preferable from the viewpoint of coatability (streaking inhibition) of the resin composition, while silicone-based surfactants are preferable from the viewpoints of the effect of oxygen concentration in the curing step on YI value and total light transmittance.

In the case of using a surfactant or leveling agent, the total incorporated amount thereof is preferably 0.001 parts by weight to 5 parts by weight and more preferably 0.01 parts by weight to 3 parts by weight based on 100 parts by weight of the polyimide precursor in the resin composition.

A portion of the polymer may be dehydrated and imidized to a degree that does not cause precipitation by preparing the aforementioned resin composition followed by heating the solution for 5 minutes to 2 hours at 130° C. to 200° C. The imidization rate can be controlled by controlling the temperature and time. Partial imidization makes it possible to improve viscosity stability of the resin precursor solution when storing at room temperature. The range of the imidization rate is preferably 5% to 70% from the viewpoints of solubility of the resin precursor in solution and storage stability of the solution.

Although there are no particular limitations on the method used to produce the resin composition of the present invention, in the case, for example, the solvent used during synthesis of the polyamide acid (a) and the organic solvent (b) are the same, the resin composition can be produced from the synthesized polyamide acid solution. In addition, the organic solvent (b) and other additives may be added and mixed by stirring over a temperature range of room temperature (25° C.) to 80° C. as necessary. A device such as the Three-One Motor (Shinto Scientific Co., Ltd.) equipped with a stirrer or a planetary centrifugal mixer can be used for stirring and mixing. Heat may also be applied to a temperature of 40° C. to 100° C. as necessary.

In addition, in the case the solvent used during synthesis of the polyamide acid (a) and the organic solvent (b) are different, after having removed the solvent in the synthesized polyamide acid solution by re-precipitation or solvent distillation to obtain the polyamide acid (a), the organic solvent (b) and other additives as necessary may be added within a temperature range of room temperature to 80° C. followed by stirring and mixing.

The resin composition of the present invention can be used to form a transparent substrate of a display device such as a liquid crystal display, organic electroluminescent display, field emission display or electronic paper. More specifically, the resin composition of the present invention can be used to form a thin film transistor (TFT) substrate, color filter substrate or transparent electrically conductive (indium thin oxide, ITO) substrate.

In addition, the resin composition has the properties indicated below in a preferable aspect thereof.

In a first aspect of the present invention, after having coated the resin composition onto the surface of a support, residual stress with the support demonstrated by a polyimide obtained by imidizing a polyimide precursor contained in the resin composition is −5 MPa to 10 MPa.

In addition, the optical absorbance at 308 nm of an alkoxysilane compound contained in the resin composition of the first aspect when in the form of a 0.001% by weight NMP solution is 0.1 to 0.5 at a solution thickness of 1 cm.

In addition, in a second aspect of the present invention, after having coated the resin composition onto the surface of a support, yellow index at a film thickness of 15 μm demonstrated by a resin obtained by imidizing a resin precursor contained in the resin composition by heating the resin composition at 300° C. to 550° C. in a nitrogen atmosphere (or by heating at 380° C. at an oxygen concentration of 2,000 ppm or less) is 14 or less.

After having coated the resin composition of the second aspect onto the surface of a substrate, residual stress demonstrated by a resin obtained by imidizing a resin precursor contained in the resin composition by heating at 300° C. to 500° C. in a nitrogen atmosphere (or by heating at 380° C. in a nitrogen atmosphere) is 25 MPa or less.

<Resin Film>

Another aspect of the present invention provides a cured product of the aforementioned resin precursor, a cured product of the aforementioned precursor mixture or a cured product of the aforementioned resin composition in the form of a resin film.

In addition, another aspect of the present invention provides a method for producing a resin film, comprising;

a step for coating the aforementioned resin composition onto the surface of a support,

a step for drying the coated resin film to remove the solvent,

a step for heating the support and the resin composition to imidize a resin precursor contained in the resin composition and form a resin film, and

a step for detaching the resin film from the support.

In a preferable aspect of the method for producing a resin film, a polyamide acid solution obtained by reacting a dianhydride component and a diamine component after dissolving in an organic solvent can be used for the resin composition.

Here, there are no particular limitations on the support provided it has heat resistance at the temperature in the subsequent drying step and has favorable detachability. Examples of supports include substrates composed of glass (such as non-alkali glass) or silicon wafer, and supports composed of polyethylene terephthalate (PET) or oriented polypropylene (OPP). In addition, examples of supports in the case of film-like molded polyimides include coated supports composed of glass or silicon wafer, and examples of supports in the case of film-like or sheet-like molded polyimides include supports composed of polyethylene terephthalate (PET) or oriented polypropylene (OPP). Other examples of substrates used include glass substrates, stainless steel, alumina, copper and nickel and other metal substrates, and resin substrates such as polyethylene glycol terephthalate, polyethylene glycol naphthalate, polycarbonate, polyimide, polyamide-imide, polyetherimide, polyether ether ketone, polyether sulfone, polyphenylene sulfone or polyphenylene sulfide.

More specifically, a resin film can be formed by coating and drying the aforementioned resin composition on an adhesive layer formed on the main surface of an inorganic substrate and curing at a temperature of 300° C. to 500° C. in an inert atmosphere. Finally, the resin film is detached from the support.

Here, a coating method using a doctor blade knife coater, air knife coater, roll coater, rotary coater, flow coater, die coater or bar coater, a coating method such as spin coating, spray coating or dip coating, or a printing technology represented by screen printing or gravure printing can be applied for the coating method.

Although the coating thickness of the resin composition of the present invention is suitably adjusted according to the thickness of the target molded product and the ratio of resin non-volatile components in the resin composition, it is normally about 1 μm to 1,000 μm. Resin non-volatile components are determined according to the previously described measurement method. Although the coating step is normally carried out at room temperature, it may also be carried out by heating the resin composition within the range of 40° C. to 80° C. for the purpose of lowering viscosity and improving workability.

A drying step is carried out following the coating step. The drying step is carried out for the purpose of removing the organic solvent. The drying step can use a device such as a hot plate, compartment dryer or conveyor dryer, and is preferably carried out at 80° C. to 200° C. and more preferably carried out at 100° C. to 150° C.

Continuing, a heating step is carried out. The heating step is a step for removing organic solvent remaining in the resin film in the drying step while also allowing the obtaining of a cured film by allowing the imidization reaction of the polyamide acid in the resin composition to progress.

The heating step is carried out using a device such as an inert gas oven, hot plate, compartment dryer or conveyor dryer. This step may be carried out simultaneous to the aforementioned drying step or may be carried out sequentially therewith.

Although the heating step may be carried out in air, it is recommended to be carried out in an inert gas atmosphere from the viewpoints of safety along with transparency and YI value of the resulting cured product. Examples of inert gases include nitrogen and argon. Although varying according to the type of the organic solvent (b), the heating temperature is preferably 250° C. to 550° C. and more preferably 300° C. to 350° C. If the temperature is lower than 250° C., imidization is inadequate, while if the temperature exceeds 550° C., there is the risk of decreased transparency or poor heat resistance of the molded polyimide. The heating time is normally about 0.5 hours to 3 hours.

In the case of the present invention, oxygen concentration during the heating step is preferably 2,000 ppm or less, more preferably 100 ppm or less and even more preferably 10 ppm or less from the viewpoint of transparency and YI value of the resulting cured product. The YI value of the resulting cured product can be made to be 15 or less by making the oxygen concentration to be 2,000 ppm or less.

A detachment step for detaching the cured film from the support may be required following the heating step depending on the application and purpose of use of the polyimide resin film. This detachment step is carried out after cooling the molded product on the base material down to about room temperature to 50° C.

Examples of methods used to carry out the detachment step are indicated below.

(1) A method consisting of obtaining a composite containing the polyimide resin film/support according to the aforementioned method followed by ablating the interface between the polyimide resin and the support by irradiating the support side with a laser to detach the polyimide resin. The type of laser is a solid (YAG) laser or gas (UV excimer) laser and the laser is used at a wavelength of 308 nm and the like (refer to Japanese Translation of PCT International Application Publication No. 2007-512568, Japanese Translation of PCT International Application Publication No. 2012-511173 and other publications).

(2) A method consisting of forming a release layer on the support prior to the step for coating the resin composition on the support followed by obtaining a composite of the polyimide resin film/release layer/support and detaching the polyimide resin film. Examples of this method include a method that uses Parylene for the release layer (registered trademark, Specialty Coating Systems, Inc.), a method that uses tungsten oxide and a method that uses release agent such as vegetable-oil-based release agent, silicone-based release agent, fluorine-based release agent and alkyd-based release agent, and these methods may also be used in combination with the laser irradiation method described in (1) above (refer to Japanese Unexamined Patent Publication No. 2010-67957, Japanese Unexamined Patent Publication No. 2013-179306 and other publications).

(3) A method consisting of obtaining a composite containing a polyimide resin film/support using an etchable metal for the support followed by etching the metal with an etchant to obtain a polyimide resin film. Examples of the etchable metal include copper (and more specifically, an electrolytic copper foil “DFF” manufactured by Mitsui Mining & Smelting Co., Ltd.) and aluminum, while examples of the etchant include ferric chloride in the case of copper and dilute hydrochloric acid in the case of aluminum.

(4) A method consisting of obtaining a composite containing a polyimide resin film/support according to the aforementioned method, affixing an adhesive film to the surface of the polyimide resin film and separating the adhesive film/polyimide resin film from the support followed by separating the polyimide resin film from the adhesive film.

Among these detachment methods, the methods described in (1) and (2) are suitable from the viewpoints of the difference in refractive indices between the front and back sides of the resulting polyimide resin film, YI value and elongation, and the method described in (1) is more suitable from the viewpoint of the difference in refractive indices between the front and back sides of the resulting polyimide resin film.

Furthermore, in the case of using copper for the support in the method described in (3), although the resulting polyimide resin film has a larger YI value and decreased elongation, this is thought to be due to some form of involvement of copper ions.

In addition, there are no particular limitations on the thickness of the resin film (cured product) according to the present embodiment, and is preferably within the range of 5 μm to 200 μm and more preferably within the range of 10 μm to 100 μm.

In a first aspect thereof, residual stress of the resin film according to the present embodiment with the support is preferably −5 MPa to 10 MPa. In addition, the yellow index at a film thickness of 10 μm is preferably 15 or less from the viewpoint of applying to a flexible display.

These properties are favorably realized by making optical absorbance at 308 nm of the alkoxysilane compound contained in the resin composition of the first aspect when in the form of a 0.001% by weight NMP solution to be 0.1 to 0.5 at a solution thickness of 1 cm. The resulting resin film can be easily detached with a laser while retaining high transparency.

In addition, the yellow index at a film thickness of 15 μm of the resin film according to the second aspect is preferably 14 or less. In addition, residual stress is preferably 25 MPa or less. In particular, yellow index at a film thickness of 15 μm is more preferably 14 or less and residual stress is more preferably 25 MPa or less. These properties are realized favorably by imidizing at an oxygen concentration of 2,000 ppm or less and temperature of 300° C. to 550° C. and more preferable 380° C.

<Laminate>

Another aspect of the present invention provides a laminate containing a support and a cured product of the aforementioned resin composition in the form of a polyimide resin film formed on the support.

In addition, another aspect of the present invention provides a method for producing a laminate, comprising:

a step for coating the aforementioned resin composition onto the surface of a support, and

a step for heating the support and the resin composition to imidize a resin precursor contained in the resin composition and form a polyimide resin film, thereby obtaining a laminate containing the support and the polyimide resin film.

This laminate can be produced by not detaching a polyimide resin film formed in the same manner as the previously described method for producing a resin film, for example, from the support.

This laminate is used, for example, to produce a flexible device. More specifically, a flexible device can be obtained that is provided with a flexible transparent substrate composed of a polyimide resin film obtained by forming an element or circuit and the like on a polyimide resin film formed on a support followed by detaching the polyimide resin film from the support.

Thus, another aspect of the present invention provides a flexible device material that contains a polyimide resin film obtained by curing the aforementioned resin precursor or the aforementioned precursor mixture.

In the present embodiment, a laminate can be obtained that comprises the lamination of a polyimide film, SiN and SiO₂ in that order. Laminating in this order not only allows the obtaining of a film that is free of warping, but also allows the obtaining of a favorable laminate without separation from an inorganic film following the formation of the laminate.

As has been explained above, a resin composition containing a resin precursor and having superior storage stability and superior coatability can be produced using the resin precursor according to the present embodiment. In addition, there is little dependency on the yellow index (YI) value of the resulting polyimide resin film on oxygen concentration during curing. In addition, residual stress is low. Thus, the resin precursor is suitable for use in a transparent substrate of a flexible display.

More specifically, in the case of forming a flexible display, a glass substrate is used for the support and a flexible substrate is formed thereon followed by the formation of a TFT and the like thereon. Although the step for forming a TFT on the substrate is typically carried out at a temperature over a wide range of 150° C. to 650° C., in order to actually realize desired performance, a TFT-IGZO (InGaZnO) oxide semiconductor or TFT (a-Si-TFT, poly-Si-TFT) is formed using inorganic materials primarily at a temperature in the vicinity of 250° C. to 350° C.

At this time, if residual stress is generated between the flexible substrate and polyimide resin, problems such as warping or damage of the glass substrate or detachment of the flexible substrate from the glass substrate occur during contraction while cooling at normal temperature after having expanded in the high-temperature TFT step. Since the coefficient of expansion of glass substrates is generally comparatively low, residual stress is generated between the glass substrate and the flexible substrate. In consideration of this point, residual stress generated between the resin film and glass in the resin film according to the present embodiment is preferably 25 MPa or less.

In addition, the yellow index of the polyimide resin film according to the present embodiment based on a film thickness of 15 μm is preferably 14 or less. In addition, less dependency on oxygen concentration in the oven used when producing the heat-cured film is advantageous for stably obtaining a resin film having a low YI value, and the YI value of the heat-cured film is preferably stable at an oxygen concentration of 2,000 ppm or less.

In addition, the tensile elongation of the resin film according to the present embodiment is more preferably 30% or more from the viewpoint of improving yield due to superior breaking strength during handling of a flexible substrate.

Another aspect of the present invention provides a polyimide resin film used to produce a display substrate. In addition, another aspect of the present invention provides a method for producing a display substrate, comprising:

a step for coating a resin composition containing a polyimide precursor onto the surface of a support,

a step for heating the support and the resin composition to imidize the polyimide precursor and form the previously described polyimide resin film,

a step for forming an element or circuit on the polyimide resin film, and

a step for forming the polyimide resin film having the element or circuit formed thereon.

In the aforementioned method, the step for coating the resin composition on the support, the step for forming the polyimide resin film, and the step for detaching the polyimide resin film can be carried out in the same manner as in the previously described methods for producing a resin film and laminate.

The resin film according to the present embodiment that satisfies the aforementioned physical properties is preferably used in applications in which the use of existing polyimide films is restricted due to the yellow color thereof, and particularly as a colorless, transparent substrate for a flexible display or protective film for a color filter. Moreover, the resin film according to the present invention can also be used in fields requiring the absence of color, transparency and low birefringence, such as the diffusive optical sheets of protective films or TFT-LCD, coating films (e.g. the interlayers of TFT-LCD, gate insulating films and liquid crystal alignment films), ITO substrates for touch panels, or plastic sheets taking the place of the cover glass of cellular telephones. The polyimide according to the present embodiment can be applied as a liquid crystal alignment film, contributes to increased aperture ratio, and enables the production of TFT-LCD having a high contrast ratio.

The resin film and laminate produced using the resin precursor according to the present embodiment can be used particularly preferably as a substrate in the production of, for example, semiconductor insulating films, TFT-LCD insulating films, electrode protective films and flexible devices. Here, examples of flexible devices include flexible displays, flexible solar cells, flexible touch panel electrode substrates, flexible lighting and flexible batteries.

### EXAMPLES

Although the following provides a more detailed explanation of the present invention based on examples thereof, these are provided for the purpose of explaining the present invention, and the scope of the present invention is not limited by the following examples.

Each of the types of evaluations used in the examples and comparative examples were carried out as indicated below.

(Measurement of Weight Average and Number Average Molecular Weight)

Weight average molecular weight (Mw) and number average molecular weight (Mn) were measured under the following conditions by gel permeation chromatography (GPC). N,N-dimethylformamide (for high-performance liquid chromatography, Wako Pure Chemical Industries, Ltd.) was used for the solvent, and solutions obtained by adding 24.8 mol/L lithium bromide hydrate (purity: 99.5%, Wako Pure Chemical Industries, Ltd.) and 63.2 mmol/L phosphoric acid (for high-performance liquid chromatography, Wako Pure Chemical Industries, Ltd.) were used prior to measurement. In addition, a calibration curve for calculating weight average molecular weight was prepared using a polystyrene standard (Tosoh Corp.).
Column: Shodex KD-806M (Showa Denko K.K.)
Flow rate: 1.0 mL/min
Column temperature: 40° C.
Pump: PU-2080Plus (Jasco Corp.)
Detector: RI-2031Plus (RI: differential refractometer, Jasco Corp.) UV-2075Plus (UV-VIS: ultraviolet-visible absorptiometer, Jasco Corp.)

(First Aspect)

Experiments were carried out on resin compositions with respect to optical absorbance of the alkoxysilane compound and properties of the resulting resin composition followed by evaluation thereof as indicated below.

### Synthesis of Alkoxysilane Compound

### Synthesis Example 1

The inside of a 50 ml separable flask was replaced with nitrogen followed by the addition of 19.5 g of N-methyl-2-pyrrolidone (NMP) to the separable flask, further adding 2.42 g (7.5 mmol) of a Raw Material Compound 1 in the form of benzophenonetetracarboxylic dianhydride (BTDA) and 3.321 g (15 mmol) of a Raw Material Compound 2 in the form of 3-aminopropyltriethoxysilane (trade name: LS-3150, Shin-Etsu Chemical Co., Ltd.), and allowing to react for 5 hours at room temperature to obtain an NMP solution of an Alkoxysilane Compound 1.

This Alkoxysilane Compound 1 was prepared in the form of a 0.001% by weight NMP solution and filled into a quartz cell having a measuring thickness of 1 cm, and optical absorbance when measured with a UV-1600 (Shimadzu Corp.) was 0.13.

### Synthesis Examples 2-5

NMP solutions of Alkoxysilane Compounds 2 to 5 were obtained in the same manner as Synthesis Example 1 with the exception of respectively changing the amount of N-methyl-2-pyrrolidone (NMP) used and the types and amounts of Raw Material Compounds 1 and 2 used in the aforementioned Synthesis Example 1 to those described in Table 1.

These alkoxysilane compounds were respectively prepared in the form of 0.001% by weight NMP solutions, and optical absorbance measured in the same manner as in the aforementioned Synthesis Example 1 is also shown in Table 1.

### Synthesis Example 6

P-18 was obtained in the same manner as Example 1 to be subsequently described with the exception of changing amount of raw material added in Example 1 to 40.2 mmol of PMDA and changing to 9.8 mmol of ODPA instead of 6FDA. The weight average molecular weight (Mw) of the resulting polyamide acid was 170,000.

In addition, the residual stress of P-18 was −1 MPa.

### Synthesis Example 7

P-19 was obtained in the same manner as Example 1 to be subsequently described with the exception of changing amount of raw material added in Example 1 to 42.6 mmol of PMDA and changing to 7.4 mmol of TAHQ instead of 6FDA. The weight average molecular weight (Mw) of the resulting polyamide acid was 175,000.

In addition, the residual stress of P-19 was 1 MPa.

### Synthesis Example 8

P-20 was obtained in the same manner as Example 1 to be subsequently described with the exception of changing amount of raw material added in Example 1 to 39.3 mmol of PMDA and changing to 10.7 mmol of BPDA instead of 6FDA. The weight average molecular weight (Mw) of the resulting polyamide acid was 175,000.

In addition, the residual stress of P-20 was 2 MPa.

TABLE 1

| | | | | | Aminotrialkoxysilane | | | Alkoxysilane | |
|---|---|---|---|---|---|---|---|---|---|
| | Amount of | Acid Dianhydride | | | Compound | | | Compound | |
| | NMP Used | | Amount Used | | | Amount Used | | | Optical |
| | (g) | Type | (g) | (mmol) | Type | (g) | (mmol) | Name | Absorbance* |
| Synthesis | 19.5 | BTDA | 2.42 | 7.5 | LS-3150 | 3.321 | 15 | Alkoxysilane | 0.130 |
| Example 1 | | | | | | | | Compound 1 | |
| Synthesis | 19.5 | BPDA | 2.21 | 7.5 | LS-3150 | 3.321 | 15 | Alkoxysilane | 0.177 |
| Example 2 | | | | | | | | Compound 2 | |
| Synthesis | 13.2 | ANPH | 1.23 | 8.0 | LS-3514 | 2.08 | 8.0 | Alkoxysilane | 0.229 |
| Example 3 | | | | | | | | Compound 3 | |
| Synthesis | 9.8 | DACA | 0.78 | 4.0 | LS-3514 | 1.97 | 8.0 | Alkoxysilane | 0.208 |
| Example 4 | | | | | | | | Compound 4 | |
| Synthesis | 19.5 | PHAA | 2.22 | 15 | LS-3150 | 3.321 | 15 | Alkoxysilane | 0.015 |
| Example 5 | | | | | | | | Compound 5 | |

*Optical absorbance at solution thickness of 1 cm when using in the form of 0.001% by weight NMP solution.

### Examples 28-31 and Comparative Examples 4 and 5

The aforementioned solution P-1 (10 g) and the types and amounts of alkoxysilane compounds shown in Table 1 were stirred well in a container to respectively prepare resin compositions containing polyimide precursor in the form of polyamide acid.

Adhesiveness, laser detachment and YI (as the value at a film thickness of 10 μm) measured according to the previously or subsequently described methods for each of the aforementioned resin compositions are each shown in Table 2.

(Measurement of Laser Detachment Strength)

Laminates obtained according to the previously described coating and curing methods having a polyimide film having a film thickness of 10 μm on non-alkali glass were irradiated with an excimer laser (wavelength: 308 nm, repetition frequency: 300 Hz) followed by determination of the minimum amount of energy required to cause detachment of the entire surface of a 10 cm×10 cm polyimide film.

TABLE 2

| | Polyimide | | Alkoxysilane | | | | | |
|---|---|---|---|---|---|---|---|---|
| | Precursor | | Compound | | | Laser | | |
| | | Amount | | Amount | | Detachment | | |
| | Type of | Used | | Used | Adhesiveness | Strength | Particle | |
| | solvent | (g) | Type | (mg) | (gf/inch) | (mJ/cm²) | Generation | YI |
| Ex. | P-1 | 10 | Alkoxysilane | 10.5 | 877 | 220 | No | 6.5 |
| 28 | | | Compound 1 | | | | | |
| Ex. | P-1 | 10 | Alkoxysilane | 10.5 | 937 | 210 | No | 6.7 |
| 29 | | | Compound 2 | | | | | |
| Ex. | P-1 | 10 | Alkoxysilane | 10.5 | 690 | 220 | No | 8.4 |
| 30 | | | Compound 3 | | | | | |
| Ex. | P-1 | 10 | Alkoxysilane | 10.5 | 750 | 220 | No | 9.9 |
| 31 | | | Compound 4 | | | | | |
| Ex. | P-18 | 10 | Alkoxysilane | 10.5 | 899 | 220 | No | 6.7 |
| 32 | | | Compound 1 | | | | | |
| Ex. | P-19 | 10 | Alkoxysilane | 10.5 | 870 | 220 | No | 6.2 |
| 33 | | | Compound 1 | | | | | |
| Ex. | P-20 | 10 | Alkoxysilane | 10.5 | 888 | 220 | No | 6.5 |
| 34 | | | Compound 1 | | | | | |
| Comp. | P-1 | 10 | — | — | 100 | 240 | Yes | 6.6 |
| Ex. 4 | | | | | | | | |
| Comp. | P-1 | 10 | Alkoxysilane | 10.5 | 400 | 240 | Yes | 10.1 |
| Ex. 5 | | | Compound 5 | | | | | |

As is clear from Table 2, the polyimide resin films obtained from resin compositions containing alkoxysilane compounds having optical absorbance of 0.1 to 0.5 and having residual stress of −5 MPa to 10 MPa in the form of the polyimide resin films of Examples 28 to 34 demonstrated high adhesiveness with the glass substrate as well as low energy levels required during detachment. In addition, there was no generation of particles during detachment.

On the other hand, in the case of Comparative Example 4, which did not contain an alkoxysilane compound, adhesiveness with the glass substrate was low and the amount of energy required during detachment was large. In addition, particles ended up being generated during detachment. In the comparative example using Alkoxysilane Compound 5 having an optical absorbance of less than 0.1 (0.015), adhesiveness was low and a large amount of energy was required during detachment. In addition, particles ended up being generated during detachment. The yellow indices of Comparative Examples 4 and 5 were also inadequate.

Based on the above results, polyimide resin films obtained from resin compositions according to a first aspect of the present invention were confirmed to be resin films that demonstrate superior adhesiveness with the glass substrate (support) and not generate particles during laser detachment.

(Second Aspect)

Experiments were carried out on polyimide precursors with respect to the contents of structural units and low molecular weight molecules having a molecular weight of less than 1,000 along with properties of the resulting resin composition followed by an evaluation thereof as indicated below.

### Example 1

The inside of a 500 ml separable flask was replaced with nitrogen followed by adding N-methyl-2-pyrrolidone (NMP, water content: 250 ppm) to the separable flask immediately after opening an 18 L drum thereof in an amount equivalent to a solid fraction content of 15% by weight, further adding 15.69 g (49.0 mmol) of 2,2′-bis(trifluoromethyl)benzidine (TFMB), and stirring to dissolve the TFMB. Subsequently, 9.82 g (45.0 mmol) of pyromellitic dianhydride (PMDA) and 2.22 g (5.0 mmol) of 4,4′-(hexafluoroisopropylidene)diphthalic anhydride (6FDA) were added, stirred for 4 hours at 80° C. in the presence of flowing nitrogen, and then cooled to room temperature followed by adding the aforementioned NMP to adjust the viscosity of the resin composition to 51,000 mPa·s and obtain an NMP solution (also referred to as varnish) P-1 of the polyamide acid. The weight average molecular weight (Mw) of the resulting polyamide acid was 180,000.

In addition, the residual stress of P-1 was −2 MPa.

### Example 2

Varnish P-2 was obtained in the same manner as Example 1 with the exception of changing the added amounts of the raw materials to 9.27 g (42.5 mmol) of PMDA and 3.33 g (7.5 mmol) of 6FDA. The weight average molecular weight (Mw) of the resulting polyamide acid was 190,000.

### Example 3

Varnish P-3 was obtained in the same manner as Example 1 with the exception of changing the added amounts of the raw materials to 7.63 g (35.0 mmol) of PMDA and 6.66 g (15.0 mmol) of 6FDA. The weight average molecular weight (Mw) of the resulting polyamide acid was 190,000.

### Example 4

Varnish P-4 was obtained in the same manner as Example 1 with the exception of changing the added amounts of the raw materials to 5.45 g (25.0 mmol) of PMDA and 11.11 g (25.0 mmol) of 6FDA. The weight average molecular weight (Mw) of the resulting polyamide acid was 200,000.

### Example 5

Varnish P-15 was obtained in the same manner as Example 1 with the exception of changing the added amounts of the raw materials to 3.27 g (15.0 mmol) of PMDA and 15.55 g (35.0 mmol) of 6FDA. The weight average molecular weight (Mw) of the resulting polyamide acid was 201,000.

### Example 6

The inside of a 500 ml separable flask was replaced with nitrogen followed by adding NMP (water content: 250 ppm) to the separable flask immediately after opening an 18 L drum thereof in an amount equivalent to a solid fraction content of 15% by weight, further adding 15.69 g (49.0 mmol) of TFMB, and stirring to dissolve the TFMB. Subsequently, 10.91 g (50.0 mmol) of PMDA were added and stirred for 4 hours at 80° C. in the presence of flowing nitrogen to obtain Varnish P-5a. The weight average molecular weight (Mw) of the resulting polyamide acid was 180,000.

Next, the inside of a 500 ml separable flask was replaced with nitrogen followed by adding NMP (water content: 250 ppm) to the separable flask immediately after opening an 18 L drum thereof in an amount equivalent to a solid fraction content of 15% by weight, further adding 15.69 g (49.0 mmol) of TFMB, and stirring to dissolve the TFMB. Subsequently, 22.21 g (50.0 mmol) of (6FDA) were added and stirred for 4 hours at 80° C. in the presence of flowing nitrogen to obtain Varnish P-5b. The weight average molecular weight (Mw) of the resulting polyamide acid was 200,000.

The Varnish P-5a and Varnish P-5b were then weighed out to a weight ratio of 85:15 followed by adding the aforementioned NMP to adjust the viscosity of the resin composition to 5,000 mPa·s and obtain Varnish P-5.

### Example 7

Varnish P-6 was obtained in the same manner as Example 2 with the exception of changing the synthesis solvent to γ-butyrolactone (GBL) (water content: 280 ppm) immediately after opening an 18 L drum thereof. The weight average molecular weight (Mw) of the resulting polyamide acid was 180,000.

### Example 8

Varnish P-7 was obtained in the same manner as Example 7 with the exception of changing the synthesis solvent to Ekuamido M100 (trade name, Idemitsu Retail Marketing Co., Ltd.) (water content: 260 ppm) immediately after opening an 18 L drum thereof. The weight average molecular weight (Mw) of the resulting polyamide acid was 190,000.

### Example 9

Varnish P-8 was obtained in the same manner as Example 7 with the exception of changing the synthesis solvent to Ekuamido B100 (trade name, Idemitsu Retail Marketing Co., Ltd.) (water content: 270 ppm) immediately after opening an 18 L drum thereof. The weight average molecular weight (Mw) of the resulting polyamide acid was 190,000.

### Example 10

Varnish P-9 was obtained in the same manner as Example 2 with the exception of not initially replacing the inside of the separable flask with nitrogen and not providing a nitrogen flow during synthesis among the experimental conditions of Example 2. The weight average molecular weight (Mw) of the resulting polyamide acid was 180,000.

### Example 11

Varnish P-10 was obtained in the same manner as Example 10 with the exception of changing the synthesis solvent to NMP (general-purpose grade instead of dehydrated grade, water content: 1120 ppm) immediately after opening a 500 ml bottle thereof. The weight average molecular weight (Mw) of the resulting polyamide acid was 170,000.

### Example 12

Varnish P-11 was obtained in the same manner as Example 10 with the exception of changing the synthesis solvent to GBL (general-purpose grade instead of dehydrated grade, water content: 1610 ppm) immediately after opening a 500 ml bottle thereof. The weight average molecular weight (Mw) of the resulting polyamide acid was 160,000.

### Example 13

Varnish P-12 was obtained in the same manner as Example 10 with the exception of changing the synthesis solvent to Ekuamido M100 (general-purpose grade instead of dehydrated grade, water content: 1250 ppm) immediately after opening a 500 ml bottle thereof. The weight average molecular weight (Mw) of the resulting polyamide acid was 170,000.

### Example 14

Varnish P-13 was obtained in the same manner as Example 10 with the exception of changing the synthesis solvent to DMAc (general-purpose grade instead of dehydrated grade, water content: 2300 ppm) immediately after opening a 500 ml bottle thereof. The weight average molecular weight (Mw) of the resulting polyamide acid was 160,000.

### Comparative Example 1

The inside of a 500 ml separable flask was replaced with nitrogen followed by adding NMP (water content: 250 ppm) to the separable flask immediately after opening an 18 L drum thereof in an amount equivalent to a solid fraction content of 15% by weight, further adding 15.69 g (49.0 mmol) of TFMB, and stirring to dissolve the TFMB. Subsequently, 10.91 g (50.0 mmol) of pyromellitic dianhydride (PMDA) were added, stirred for 4 hours at 80° C. in the presence of flowing nitrogen and then cooled to room temperature followed by adding the aforementioned NMP to adjust the viscosity of the resin composition to 51,000 mPa·s and obtain Varnish P-14. The weight average molecular weight (Mw) of the resulting polyamide acid was 180,000.

### Comparative Example 2

Varnish P-16 was obtained in the same manner as Example 10 with the exception of changing the synthesis solvent to DMAc contained in a 500 ml bottle thereof and allowed to stand for one month or more after opening (water content: 3150 ppm), and changing the amount of TFMB added to 16.01 g (50.0 mmol). The weight average molecular weight (Mw) of the resulting polyamide acid was 170,000.

### Comparative Example 3

Varnish P-17 was obtained in the same manner as Example 10 with the exception of changing the synthesis solvent to DMF contained in a 500 ml bottle thereof and allowed to stand for one month or more after opening (water content: 3070 ppm), and changing the amount of TFMB added to 16.01 g (50.0 mmol). The weight average molecular weight (Mw) of the resulting polyamide acid was 170,000.

Each of the properties were measured for the resin compositions of each the examples and comparative examples prepared in the manner described above and then evaluated. The results are summarized in Table 3.

<Evaluation of Content of Molecules having Molecular Weight of Less Than 1,000>

The content of molecules having a molecular weight of less than 1,000 was calculated from the equation below using the measurement results of GPC.

Content of molecules having molecular weight of less than 1,000(%)=Peak area of molecules having molecular weight of less than 1,000/peak area of entire molecular weight distribution×100

<Evaluation of Water Content>

The water contents of the synthesis solvent and resin composition (varnish) were measured using a Karl Fischer moisture titrator (Model AQ-300 Trace Moisture Titrator, Hiranuma Sangyo Co., Ltd.).

<Evaluation of Resin Composition Viscosity Stability>

Samples were prepared from the compositions prepared in each of the aforementioned examples and comparative examples after allowing to stand undisturbed for 3 days at room temperature, and the resulting samples were then used to measure viscosity at 23° C. Samples prepared by further allowing the samples to stand undisturbed for 2 weeks at room temperatures were then again used to measure viscosity at 23° C.

Viscosity was measured using a viscometer equipped with a temperature controller (Model TV-22, Toki Sangyo Co., Ltd.).

The rate of change in viscosity after 4 weeks at room temperature was calculated according to the equation below using the aforementioned measured values.

Rate of change in viscosity after 2 weeks (%)=[(sample viscosity after 2 weeks)−(sample viscosity after initial preparation)]/(sample viscosity after initial preparation)×100

The rate of change in viscosity after 2 weeks was evaluated according to the criteria indicated below.
Excellent: Rate of change in viscosity of 5% or less (excellent storage stability)
Good: Rate of change in viscosity of greater than 5% to less than 10% (good storage stability)
Unacceptable: Rate of change in viscosity of greater than 10% (poor storage stability)

<Evaluation of Coatability in terms of Edge Cissing>

Resin compositions respectively prepared in each of the aforementioned examples and comparative examples were coated onto non-alkali glass substrates (size: 10 mm×10 mm, thickness: 0.7 mm) using a bar coater to a cured film thickness of 15 μm. After allowing to stand for 5 hours at room temperature, the degree of cissing of the coating edges was observed. The sum of the amount of cissing over the width of the four sides of the coated films was calculated and evaluated according to the criteria indicated below.
Excellent: Amount of cissing of coated edges (sum of 4 sides) of greater than 0 to 5 mm or less (excellent edge cissing)
Good: Amount of cissing of coated edges (sum of 4 sides) of greater than 5 mm to 15 mm or less (good edge cissing)
Unacceptable: Amount of cissing of coated edges (sum of 4 sides) of greater than 15 mm (unacceptable edge cissing)

<Evaluation of Residual Stress>

Resin compositions, for which the amounts of warping had been preliminarily measured using a residual stress measuring instrument (Model FLX-2320, KLA-Tencor Corp.), were coated onto 6-inch silicon wafers having a thickness of 625 μm±25 pmu using a bar coater followed by baking for 60 minutes at 140° C. Subsequently, the coated wafers were subjected to heat curing treatment (curing treatment) for 60 minutes at 380° C. using a vertical curing oven (Model VF-2000B, Koyo Lindberg Ltd.) after adjusting the oxygen concentration to 10 ppm or less to prepare silicon wafers provided with a polyimide resin film having a cured film thickness of 15 μm. The amount of warping of the wafers was measured using the previously described residual stress measuring instrument followed by evaluation of the amount of residual stress generated between the silicon wafer and resin film.
Excellent: Residual stress of greater than −5 MPa to 15 MPa or less (excellent residual stress)
Good: Residual stress of greater than 15 MPa to 25 MPa or less (good residual stress)
Unacceptable: Residual stress of greater than 25 MPa (unacceptable residual stress)

<Evaluation of Yellow Index (YI) Value>

Resin compositions respectively prepared in the aforementioned examples and comparative examples were coated to a cured film thickness of 15 μm onto 6-inch silicon wafer substrates provided with a vapor-deposited aluminum layer on the surface thereof followed by baking for 60 minutes at 140° C. Subsequently, the coated wafer substrates were subjected to heat curing treatment for 1 hour at 380° C. using a vertical curing oven (Model VF-2000B, Koyo Lindberg Ltd.) after adjusting the oxygen concentration to 10 ppm or less to prepare wafers having a polyimide resin film formed thereon. The wafers were immersed in dilute aqueous hydrochloric acid solution to detach the polyimide resin film and obtain resin films. Yellow indices of the resulting polyimide resin films were determined by measuring YI values (at a film thickness of 10 μm for the first aspect and film thickness of 15 μm for the second aspect) with the SE600 Spectrophotometer manufactured by Nippon Denshoku Industries Co., Ltd. using a D65 light source.

<Evaluation of Haze of Polyimide Resin Film Formed with Inorganic Film>

An inorganic film in the form of a silicon nitride (SiNx) film was formed at a thickness of 100 nm and temperature of 350° C. using CVD on a polyimide resin film using wafers on which were formed the polyimide resin film prepared in the aforementioned section on <Evaluation of Yellow Index (YI) Value> to obtain laminated wafers having an inorganic film/polyimide resin formed thereon.

The laminated wafers obtained as described above were immersed in dilute aqueous hydrochloric acid solution to detach the two layers of the inorganic film and polyimide film from the wafer and obtain samples of polyimide films having an inorganic film formed on the surface thereof. These samples were then used to measure haze in compliance with the Transparency Test Method of JIS K7105 using the Model SC-3H Haze Meter manufactured by Suga Test Instruments Co., Ltd.

Measurement results were evaluated according to the criteria indicated below.
Excellent: Haze value of 5 or less (excellent haze)
Good: Haze value of greater than 5 to 15 or less (good haze)
Unacceptable: Haze value of greater than 15 (unacceptable haze)

The results of evaluating each parameter as described above are shown in Table 3.

TABLE 3

| | | | | | | | | Molecular |
|---|---|---|---|---|---|---|---|---|
| | Monomer | | | | | Solvent | Weight | weight |
| | PMDA | 6FDA | TFM3 | | | water | avg. | <1000 |
| | (molar | (molar | (molar | Polyimide | Synthesis | content | molecular | content |
| | ratio) | ratio) | ratio) | precursor | solvent | (ppm) | weight | (%) |
| Ex. 1 | 90 | 10 | 98 | P-1 | NMP | 250 | 180,000 | 0.01 |
| Ex. 2 | 85 | 15 | 98 | P-2 | NMP | 250 | 190,000 | 0.01 |
| Ex. 3 | 70 | 30 | 98 | P-3 | NMP | 250 | 190,000 | 0.01 |
| Ex. 4 | 50 | 50 | 98 | P-4 | NMP | 250 | 200,000 | 0.02 |
| Ex. 5 | 30 | 70 | 98 | P-15 | NMP | 250 | 201,000 | 0.01 |
| Ex. 6 | PMDA/TFMB or | | | P-5 | NMP | 250 | 180,000/ | 0.01 |
| | 6FDA/TFMB | | | | | | 200,000 | |
| | mixture | | | | | | | |
| Ex. 7 | 85 | 15 | 98 | P6 | GBL | 280 | 180,000 | 0.05 |
| Ex. 8 | 85 | 15 | 98 | P-7 | M100 | 260 | 190,000 | 0.02 |
| Ex. 9 | 85 | 15 | 98 | P-8 | B100 | 270 | 190,000 | 0.02 |
| Ex. 10 | 85 | 15 | 98 | P-9 | NMP | 250 | 180,000 | 2.1 |
| Ex. 11 | 85 | 15 | 98 | P-10 | NMP | 1120 | 170,000 | 3.6 |
| Ex. 12 | 85 | 15 | 98 | P-11 | GBL | 1610 | 160,000 | 4.6 |
| Ex. 13 | 85 | 15 | 98 | P-12 | M100 | 1250 | 170,000 | 3.8 |
| Ex. 14 | 85 | 15 | 98 | P-13 | DMAc | 2300 | 160,000 | 3.7 |
| Comp. Ex. 1 | 100 | 0 | 98 | P-14 | NMP | 250 | 180,000 | 0.01 |
| Comp. Ex. 2 | 85 | 15 | 100 | P-16 | DMAc | 3150 | 170,000 | 9.1 |
| Comp. Ex. 3 | 85 | 15 | 100 | P-17 | DMF | 3070 | 170,000 | 8.3 |

| | Resin | | | | | Haze |
|---|---|---|---|---|---|---|
| | composition | | Edge | | | after |
| | water | | cissing | Residual | | forming |
| | content | Viscosity | durding | stress | | inorganic |
| | (ppm) | stability | coating | (MPa) | YI | film |
| Ex. 1 | 340 | Excellent | Excellent | Excellent | 8 | Excellent |
| Ex. 2 | 320 | Excellent | Excellent | Excellent | 8 | Excellent |
| Ex. 3 | 310 | Excellent | Excellent | Excellent | 7 | Excellent |
| Ex. 4 | 320 | Excellent | Excellent | Good | 6 | Excellent |
| Ex. 5 | 320 | Excellent | Good | Unacceptable | 6 | Good |
| Ex. 6 | 330 | Excellent | Excellent | Good | 8 | Excellent |
| Ex. 7 | 370 | Excellent | Good | Excellent | 7 | Excellent |
| Ex. 8 | 350 | Excellent | Excellent | Excellent | 8 | Excellent |
| Ex. 9 | 370 | Excellent | Excellent | Excellent | 7 | Excellent |
| Ex. 10 | 890 | Good | Good | Good | 7 | Good |
| Ex. 11 | 1520 | Good | Good | Good | 7 | Good |
| Ex. 12 | 2050 | Good | Good | Good | 8 | Good |
| Ex. 13 | 1670 | Good | Good | Good | 7 | Good |
| Ex. 14 | 2910 | Good | Unacceptable | Good | 7 | Good |
| Comp. Ex. 1 | 340 | Excellent | Good | Unacceptable | 16 | Good |
| Comp. Ex. 2 | 5210 | Unacceptable | Unacceptable | Unacceptable | 7 | Unacceptable |
| Comp. Ex. 3 | 5170 | Unacceptable | Unacceptable | Unacceptable | 7 | Unacceptable |

As is clear from Table 3, in Examples 1 to 14, which contained two structural units represented by general formulas (1) and (2) (PMDA and 6FDA) and had a moisture content of the solvent of less than 3,000 ppm, the content of polyimide precursor in the resulting resin composition having a molecular weight of less than 1,000 was less than 5% by weight. These resin compositions demonstrated viscosity stability during storage of 10% or less while simultaneously realizing edge cissing during coating of 15 mm or less.

Polyimide resin films obtained by curing these resin compositions simultaneously demonstrated sufficiently low residual stress, yellow indices of 14 or less (film thickness: 15 μm) and haze of 15 or less for an inorganic film formed on the polyimide resin film, thereby confirming these polyimide resin films to have superior properties.

In the case of a molar ratio of PMDA and 6FDA of 90/10 to 50/50, residual stress was 25 MPa or less and particularly favorable properties were obtained. In contrast, in Example 5, in which the molar ratio of PMDA and 6FDA was 30:70, residual stress of the resin film was inadequate. In addition, in Comparative Example 1, which contained only one of the structural units, namely that in which the molar ratio of PMDA and 6FDA was 100:0, residual stress and yellow index of the polyimide resin film were inadequate.

In addition, in Comparative Examples 2 and 3, in which the solvent water content was 3,000 ppm or more, the content of polyimide precursor having a molecular weight of less than 1,000 was 5% by weight or more. In this case, viscosity stability during storage was low and edge cissing during coating was inadequate. A polyimide resin film using this resin composition demonstrated inadequate residual stress and haze.

Experiments were carried out in the following Examples 15 to 21 on the oxygen concentration during heat curing and the resin film detachment method.

### Example 15

Varnish P-2 of the polyimide precursor obtained in Example 2 was coated onto a non-alkali glass substrate (thickness: 0.7 mm) using a bar coater. Continuing, after leveling for 5 minutes to 10 minutes at room temperature, the coated substrate was heated for 60 minutes at 140° C. in a hot air oven to prepare a glass substrate laminate coated with a coating film. The thickness of the coating film was made to be such that the cured film thickness was 15 μm. Next, the laminate was subjected to heat curing treatment for 60 minutes at 380° C. using a vertical curing oven (Model VF-2000B, Koyo Lindberg Ltd.) after adjusting the oxygen concentration to 10 ppm or less to imidize the coating film and prepare a glass substrate laminate having a polyimide film (polyimide resin film) formed thereon. After allowing the cured laminate to stand for 24 hours at room temperature, the polyimide film was detached from the glass substrate using the method described below.

Namely, the glass substrate was irradiated with laser light from the side of the glass substrate towards the polyimide film using the third harmonic of an Nd:YAG laser (355 nm). The glass substrate was irradiated at the minimum level of radiation energy enabling detachment by incrementally increasing the irradiated energy to detach the polyimide film from the glass substrate and obtain a polyimide film.

### Example 16

A glass substrate was used in which a release layer in the form of Parylene HT (registered trademark, Specialty Coating Systems, Inc.) was formed on the glass substrate instead of the glass substrate used in Example 14.

The glass substrate having Parylene HT formed thereon was prepared using the method described below.

Parylene precursor (Parylene dimer) was placed in a heat deposition apparatus, and a glass substrate (15 cm×15 cm) covered with a hollow pad (8 cm×8 cm) was placed in the sample chamber. The Parylene precursor was vaporized at 150° C. in a vacuum and then decomposed at 650° C. followed by introducing into the sample chamber. Parylene was deposited at room temperature on the area not covered by the pad to prepare a glass substrate (8 cm×8 cm) on which was formed the Parylene HT represented by the following formula (9).

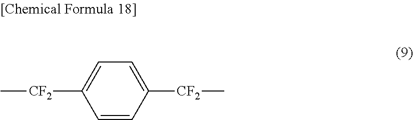

A glass substrate was then prepared having the polyimide film/Parylene HT formed thereon using the same method as that of Example 15.

Subsequently, when a cut was made in the glass laminate outside the 8 cm×8 cm area where the Parylene HT was not formed, the polyimide film was able to be easily detached from the glass substrate to obtain the polyimide film.

### Example 17

A polyimide film was prepared with reference to the method described in Example 1 of Patent Document 4 of the prior art.

A copper foil having a polyimide film formed thereon was prepared according to the same method as Example 14 using copper foil having a thickness of 18 μm (electrolytic copper foil “DFF” manufactured by Mitsui Mining & Smelting Co., Ltd.) instead of the glass substrate used in Example 15. Next, this copper foil having a polyimide film formed thereon was immersed in ferric chloride etching solution to remove the copper foil and obtain a polyimide film.

### Example 18

A polyimide film was prepared with reference to the method described in Example 5 of Patent Document 4 of the prior art.

After preparing a glass substrate having a polyimide film formed thereon obtained according to the same method as Example 15, an adhesive film (PET film, thickness: 100 μm, adhesive thickness: 33 μm) was affixed to the surface of the polyimide film followed by detaching the polyimide film from the glass substrate and separating the polyimide film from the adhesive film to obtain a polyimide film.

### Example 19

A polyimide film was obtained by carrying out the same procedure as Example 15 with the exception of adjusting the oxygen concentration during curing to 100 ppm among the experimental conditions of Example 15.

### Example 20

A polyimide film was obtained by carrying out the same procedure as Example 15 with the exception of adjusting the oxygen concentration during curing to 2,000 ppm among the experimental conditions of Example 15.

### Example 21

A polyimide film was obtained by carrying out the same procedure as Example 15 with the exception of adjusting the oxygen concentration during curing to 5,000 ppm among the experimental conditions of Example 15.

Each of the properties were measured for the polyimide resin films of each the examples obtained in the manner described above and then evaluated.

<Evaluation of Difference in Refractive Indices between Front and Back of Polyimide Resin Film>

The refractive indices n of the front and back sides of the polyimide resin films obtained in Examples 15 to 21 were measured with the Model 2010/M Prism Coupler (trade name, Merricon Ltd.).

<Evaluation of Yellow Index (YI) Value>

The yellow indices (YI) of the polyimide resin films obtained in Examples 15 to 21 were measured for YI value (at a film thickness of 10 Mm) with the SE600 Spectrophotometer manufactured by Nippon Denshoku Industries Co., Ltd. using a D65 light source.

<Evaluation of Tensile Elongation>

A tensile test was carried out on the polyimide resin films obtained in Examples 15 to 21 in at atmosphere at a temperature of 23° C. and humidity of 50% RH with a tensile tester (Model RTG-1210, A & D Co., Ltd.) using resin film samples measuring 5 mm×50 mm and having a thickness of 15 μm followed by measurement of tensile elongation.

The results of evaluating each of the parameters as described above are shown in Table 4.

TABLE 4

| | | | | Difference | | |
|---|---|---|---|---|---|---|
| | | | | in front | | |
| | | Curing Oxygen | Polyimide | and back | | |
| | Resin | Concentration | detachment | refractive | YI | |
| | Composition | (ppm) | method | indices | value | Elongation |
| Ex. 15 | P-2 | 10 | Laser detachment | 0 | 9 | 40 |
| Ex. 16 | P-2 | 10 | Release layer | 0.01 | 8 | 40 |
| Ex. 17 | P-2 | 10 | Copper foil | 0.01 | 18 | 10 |
| | | | etching | | | |
| Ex. 18 | P-2 | 10 | Adhesive film | 0.02 | 9 | 30 |
| Ex. 19 | P-2 | 100 | Laser | 0 | 9 | 35 |
| | | | detachment | | | |
| Ex. 20 | P-2 | 2000 | Laser | 0 | 13 | 35 |
| | | | detachment | | | |
| Ex. 21 | P-2 | 5000 | Laser | 0 | 23 | 35 |
| | | | detachment | | | |

As is clear from Table 4, yellow indices of the polyimide resin films were able to be further lowered by making the oxygen concentration during curing to be 2,000 ppm, 100 ppm or 10 ppm, and the use of laser detachment and/or a release film for the detachment method was confirmed to satisfy requirements for difference in refractive indices between the front and back sides of the resin film, low yellow index and adequate tensile elongation.

In addition, the yellow index of the polyimide resin film was high in Example 17, in which the polyimide resin film was detached by etching using a copper foil for the support. In addition, tensile elongation was low. In addition, there was a large difference in refractive indices between the front and back sides of the polyimide resin film in the case of Example 18 that used an adhesive film to detach the polyimide resin film. In addition, tensile elongation was inadequate.

On the basis of the above results, polyimide resin films obtained from the polyimide precursor according to the present invention were confirmed to have low yellow indices, low residual stress, superior mechanical properties and little effect of oxygen concentration during curing on the yellow indices thereof.

Experiments were carried out in the following Examples 22 to 27 on effects in the case of adding a surfactant and/or alkoxysilane to the polyimide precursor.

The dependency of coating streaking and yellow index (YI) value on oxygen concentration during curing was evaluated using the varnish of the polyimide precursor obtained in Example 2.

### Example 22

The Varnish P-2 of the polyimide precursor obtained in Example 2 was used.

### Example 23

0.025 parts by weight of Silicon-based Surfactant 1 (DBE-821, trade name, Gelest Inc.) were dissolved in the varnish of the polyimide precursor obtained in Example 2 based on 100 parts by weight of resin followed by passing through a 0.1 μm filter to prepare a resin composition.

### Example 24

0.025 parts by weight of Silicon-based Surfactant 2 (Megaface F171, trade name, DIC Corp.) were dissolved in the varnish of the polyimide precursor obtained in Example 2 based on 100 parts by weight of resin followed by passing through a 0.1 μm filter to prepare a resin composition.

### Example 25

0.5 parts by weight as the amount of the following structure of Alkoxysilane Compound 1 represented by the following formula were dissolved in the varnish of the polyimide precursor obtained in Example 2 based on 100 parts by weight of resin followed by passing through a 0.1 μm filter to prepare a polyimide precursor resin composition.

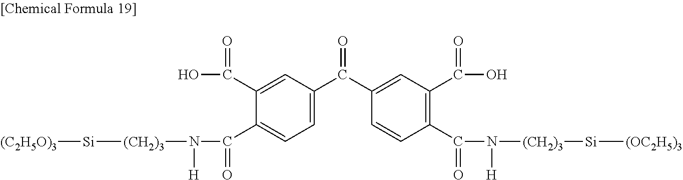

### Example 26

0.5 parts by weight as the amount of the following structure of Alkoxysilane Compound 2 represented by the following formula were dissolved in the varnish of the polyimide precursor obtained in Example 2 based on 100 parts by weight of resin followed by passing through a 0.1 μm filter to prepare a polyimide precursor resin composition.

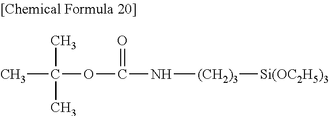

### Example 27

0.025 parts by weight of the aforementioned Surfactant 1 and 0.5 parts by weight of the aforementioned Alkoxysilane Compound 1 were dissolved in the varnish of the polyimide precursor obtained in Example 2 based on 100 parts by weight of resin followed by passing through a 0.1 μm filter to prepare a polyimide precursor resin composition.

Each of the properties were measured and evaluated for the resin compositions of each of the examples obtained in the manner described above.

<Evaluation of Coatability in Terms of Streaking>

The resin compositions obtained in Examples 21 to 26 were coated onto a non-alkali glass substrate (size: 37 mm×47 mm, thickness: 0.7 mm) to a cured film thickness of 15 μm using a bar coater. After allowing to stand for 10 minutes at room temperature, the cured substrates were visually confirmed for occurrence of streaks in the coating film. The number of streaks was determined by using the average number of streaks for three rounds of coating. Streaking was then evaluated according to the criteria indicated below.
Excellent: No continuous streaks more than 1 mm wide and 1 mm long (excellent streaking)
Good: 1 or 2 streaks (good streaking)
Acceptable: 3 to 5 streaks (acceptable streaking)

<Dependency of Yellow Index (YI) Value on Oxygen Concentration during Curing>

The glass substrates having coating films formed thereon obtained in the evaluation of streaking were cured for 60 minutes at 380° C. after adjusting the oxygen concentration in the curing oven to 10 ppm, 100 ppm and 2,000 ppm, respectively. Yellow index (YI) value of a polyimide film having a thickness of 15 μm was measured with the SE600 Spectrophotometer manufactured by Nippon Denshoku Industries Co., Ltd. using a D65 light source. The dependency of YI value on oxygen concentration during curing was then evaluated according to the criteria indicated below.

The results of evaluating each of the parameters as described above are shown in Table 5.

TABLE 5

| | | | | | Dependency |
|---|---|---|---|---|---|
| | | Added Additives | | | of YI Value |
| | Resin | | Alkoxysilane | Evaluation | on Oxygen |
| | Compo- | Surfactant | Compound | of Coating | Concen- |
| | sition | (c) | (d) | Streaking | tration |
| Example | P-2 | — | — | Accept- | 8/9/13 |
| 22 | | | | able | |
| Example | P-2 | Surfactant | — | Good | 8/9/9 |
| 23 | | 1 | | | |
| Example | P-2 | Surfactant | — | Good | 8/9/11 |
| 24 | | 2 | | | |
| Example | P-2 | — | Compound | Good | 8/9/11 |
| 25 | | | 1 | | |
| Example | P-2 | — | Compound | Good | 8/9/11 |
| 26 | | | 2 | | |
| Example | P-2 | Surfactant | Compound | Excel- | 8/9/9 |
| 27 | | 1 | 1 | lent | |

Furthermore, the YI values shown in Table 5 indicate the results when adjusting oxygen concentration in the oven to 10 ppm, 100 ppm and 2,000 ppm, respectively (10 ppm/100 ppm/2,000 ppm).

As is clear from Table 5, in Examples 23 to 27, in which a surfactant and/or alkoxysilane compound was added to the resin composition, the number of streaks during coating of the resin compositions was 2 or less and the dependency of yellow indices of the polyimide resin films on oxygen concentration during curing was low, thereby confirming that these requirements are satisfied simultaneously in comparison with Example 21 in which these components were not added.

As is clear from the aforementioned examples, a resin composition using the polyimide precursor according to the first aspect of the present invention contains an alkoxysilane compound in which optical absorbance at 308 nm when in the form of a 0.001% by weight NMP solution is 0.1 to 0.5 at a solution thickness of 1 cm.

In addition, residual stress between the support and the polyimide resin film obtained by curing the resin composition is −5 MPa to 10 MPa.

On the basis of these results, a polyimide resin film obtained from the resin composition according to the first aspect of the present invention was confirmed to be a resin film that has superior adhesiveness with a glass substrate (support) and does not cause generation of particles during laser detachment.

In addition, as is clear from the aforementioned examples, a resin composition using the polyimide precursor according to the second aspect of the present invention simultaneously satisfies the requirements of:

(1) viscosity stability during storage of 10% or less, and

(2) edge cissing during coating of 15 mm or less.

In addition, a polyimide resin film obtained by curing the resin composition simultaneously satisfies the requirements of:

(3) residual stress of 25 MPa or less,

(4) yellow index of 14 or less (film thickness: 15 μm), and

(5) haze of an inorganic film formed on the polyimide resin film of 15 or less.

The polyimide resin film:

(6) is able to further decrease yellow index by making the oxygen concentration during curing to be 2,000 ppm, 100 ppm or 10 ppm, and

(7) satisfy the requirements for difference in refractive indices between the front and back sides of the resin film and low yellow index by using laser detachment and/or a release layer for the detachment method.

Adding a surfactant and/or alkoxysilane compound to the resin composition makes it possible to simultaneously satisfy the requirements of:

(8) two or fewer streaks for the number of streaks when coating the resin composition, and

(9) low dependency of yellow index of a polyimide resin film on oxygen concentration during curing.

On the basis of these results, a polyimide resin film obtained from the polyimide precursor according to the present invention was confirmed to be a resin film that has low yellow index, low residual stress, superior mechanical properties and little effect of oxygen concentration during curing on yellow index.

Furthermore, the present invention is not limited to the aforementioned embodiments, and can be carried out after modifying in various ways.

### INDUSTRIAL APPLICABILITY

The present invention can be preferably used in the production of semiconductor insulating films, TFT-LCD insulating films, electrode protective films or flexible displays, and particularly as a substrate for a touch panel ITO electrode.

1. A resin composition containing a polyimide precursor (a), an organic solvent (b) and an alkoxysilane compound (d); wherein,
after having coated the resin composition onto the surface of a support, residual stress with the support demonstrated by a polyimide obtained by imidizing the polyimide precursor (a) is −5 MPa to 10 MPa, and
absorbance of the alkoxysilane compound (d) at 308 nm when in the form of a 0.001% by weight NMP solution is 0.1 to 0.5 at a solution thickness of 1 cm.

2. The resin composition according to claim 1, wherein the alkoxysilane compound (d) is a compound obtained by reacting an acid dianhydride represented by the following formula (1) with an aminotrialkoxysilane compound: 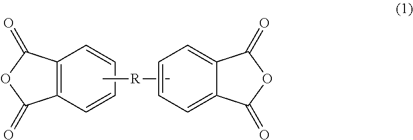
wherein R represents a single bond, oxygen atom, sulfur atom, or alkylene group having 1 to 5 carbon atoms.

3. The resin composition according to claim 1 wherein the alkoxysilane compound (d) is at least one type of compound selected from the group consisting of compounds respectively represented by the following formulas (2) to (4):

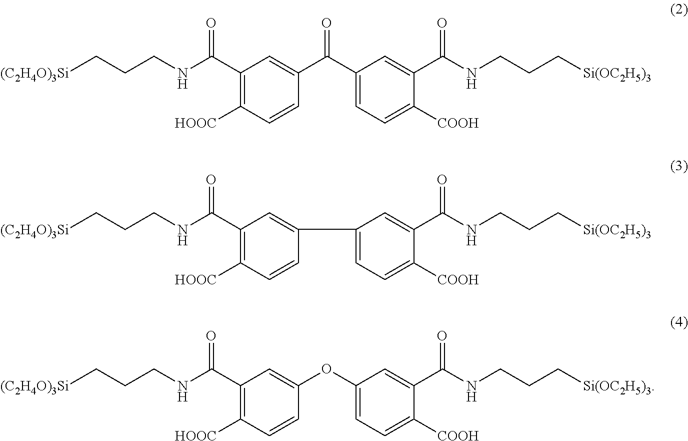

4. The resin composition according to claim 1, wherein the polyimide precursor (a) has a structural unit represented by the following formula (5): 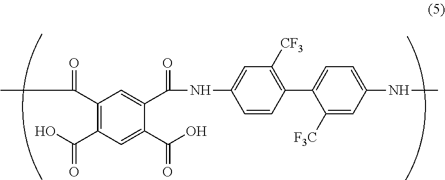
and a structural unit represented by the following formula (6):

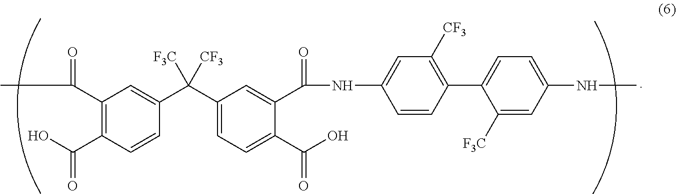

5. The resin composition according to claim 1, wherein, in the polyimide precursor (a), the molar ratio of the structural unit represented by formula (5) to the structural unit represented by formula (6) is 90/10 to 50/50.

6. A resin composition containing a polyimide precursor (a) and an organic solvent (b); wherein, the polyimide precursor (a) has a structural unit represented by the following formula (5): 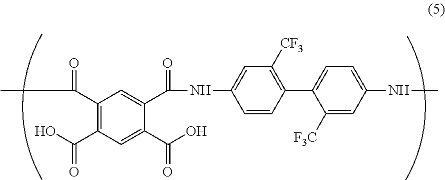
and a structural unit represented by the following formula (6): 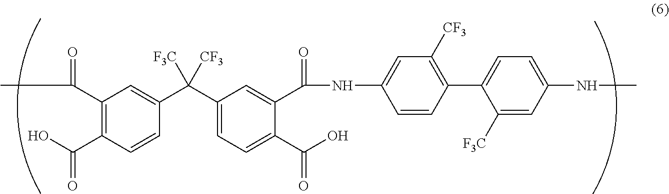
and the content of polyimide precursor having a molecular weight of less than 1,000 based on the total weight of the polyimide precursor (a) is less than 5% by weight.

7. The resin composition according to claim 6, wherein the content of the polyimide precursor (a) having a molecular weight of less than 1,000 is less than 1% by weight.

8. The resin composition according to claim 6, wherein, in the polyimide precursor (a), the molar ratio of the structural unit represented by formula (5) to the structural unit represented by formula (6) is 90/10 to 50/50.

9. A resin composition containing a polyimide precursor (a) and an organic solvent (b); wherein, the polyimide precursor (a) is a mixture of a polyimide precursor having a structural unit represented by the following formula (5): 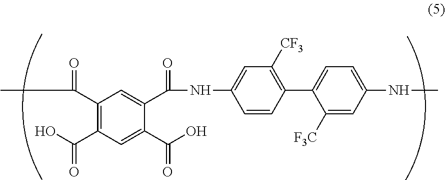
and a polyimide precursor having a structural unit represented by the following formula (6):

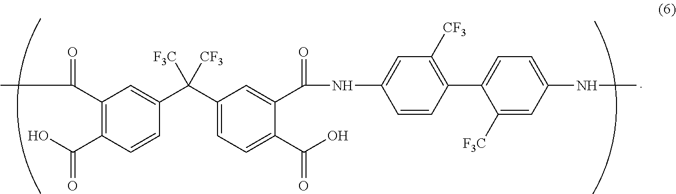

10. The resin composition according to claim 9, wherein the weight ratio of the polyimide precursor having a structural unit represented by formula (5) to the polyimide precursor having a structural unit represented by formula (6) is 90/10 to 50/50.

11. The resin composition according to claim 1, wherein the water content is 3000 ppm or less.

12. The resin composition according to claim 1, wherein the organic solvent (b) is an organic solvent having a boiling point of 170° C. to 270° C.

13. The resin composition according to claim 1, wherein the organic solvent (b) is an organic solvent having a vapor pressure at 20° C. of 250 Pa or lower.

14. The resin composition according to claim 12, wherein the organic solvent (b) is at least one type of organic solvent selected from the group consisting of N-methyl-2-pyrrolidone, γ-butyrolactone and a compound represented by the following formula (7): 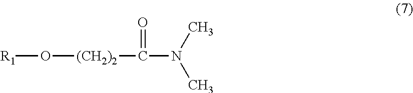
wherein, R₁ represents a methyl group or n-butyl group.

15. The resin composition according to claim 1, further containing a surfactant (c).

16. The resin composition according to claim 15, wherein the surfactant (c) is one or more types of surfactants selected from the group consisting of fluorine-based surfactants and silicone-based surfactants.

17. The resin composition according to claim 15, wherein the surfactant (c) is a silicone-based surfactant.

18. The resin composition according to claim 6, further containing an alkoxysilane compound (d).

19. A polyimide resin film obtained by heating the resin composition according to claim 1.

20. A resin film containing the polyimide resin film according to claim 19.

21. A method for producing a resin film, comprising:
coating the resin composition according to claim 1 on the surface of a support,
drying the coated resin composition and removing the solvent,
a heating the support and the resin composition to imidize a resin precursor contained in the resin composition and form a polyimide resin film, and
detaching the polyimide resin film from the support.

22. The method for producing a resin film according to claim 21, comprising forming a release layer on the support prior to coating the resin composition on the surface of the support.

23. The method for producing a resin film according to claim 21, wherein the oxygen concentration in the heating the support is 2000 ppm or less.

24. The method for producing a resin film according to claim 21, wherein the oxygen concentration in the heating the support is 100 ppm or less.

25. The method for producing a resin film according to claim 21, wherein the oxygen concentration in the heating the support is 10 ppm or less.

26. The method for producing a resin film according to claim 21, wherein the detaching the polyimide resin film from the support comprises detaching the polyimide resin film after having irradiated with a laser from the side of the support.

27. The method for producing a resin film according to claim 21, wherein the detaching the polyimide resin film having an element or circuit formed thereon from the support comprises detaching the polyimide resin film from a composite containing the polyimide resin film, a release layer, and the support.

28. A laminate containing a support, and a cured product of the resin composition according to claim 6 in the form of a polyimide resin film.

29. A method for producing a laminate, comprising:
coating the resin composition according to claim 6 on the surface of a support, and
heating the support and the resin composition to imidize the resin precursor contained in the resin composition and form a polyimide resin film.

30. A method for producing a display substrate, comprising:
coating the resin composition according to claim 6 on a support and heating to form a polyimide resin film,
forming an element or circuit on the polyimide resin film, and
detaching the polyimide resin film having an element or circuit formed thereon from the support.

31. A display substrate formed according to the method for producing a display substrate according to claim 30.

32. A laminate obtained by laminating the polyimide film according to claim 19, SiN and SiO₂ in that order.
